(19) United States
(12) Patent Application Publication
(10) Pub. No.: US 2024/0332309 A1
(43) Pub. Date: Oct. 3, 2024

(54) DISPLAY DEVICE

(71) Applicant: Samsung Display Co., Ltd., Yongin-si (KR)

(72) Inventors: Won Jun LEE, Yongin-si (KR); Kwi Hyun KIM, Yongin-si (KR); Dong Woo KIM, Yongin-si (KR); Do Yeong PARK, Yongin-si (KR)

(21) Appl. No.: 18/604,289

(22) Filed: Mar. 13, 2024

(30) Foreign Application Priority Data
Mar. 29, 2023 (KR) 10-2023-0040980

(51) Int. Cl. H01L 27/12; H10K 59/123; H10K 59/40; H10K 102/00

(52) U.S. Cl. CPC H01L 27/1225; H01L 27/1255; H10K 59/123; H10K 59/40; H10K 2102/311

(57) ABSTRACT

The present disclosure relates to a display device, and more particularly, to a display device capable of improving image quality by reducing or minimizing voltage fluctuations of a gate electrode of a driving transistor. The display device includes a substrate; a field effect transistor on the substrate; an oxide-based transistor on a layer different from the field effect transistor and connected to the field effect transistor through a contact hole in an insulating layer; and a pixel electrode on the oxide-based transistor.

### CROSS-REFERENCE TO RELATED APPLICATION

The present application claims priority to and the benefit of Korean Patent Application No. 10-2023-0040980, filed on Mar. 29, 2023, in the Korean Intellectual Property Office, the entire disclosure of which is incorporated by reference herein.

### BACKGROUND

### 1. Field

The present disclosure relates to a display device, and more particularly, to a display device capable of improving image quality.

### 2. Description of the Related Art

An organic light emitting display device includes a display element of which luminance is changed by current, for example, an organic light emitting diode.

### SUMMARY

Aspects and features of embodiments of the present disclosure provide a display device capable of improving image quality by reducing or minimizing voltage fluctuations of a gate electrode of a driving transistor.

However, aspects and features of embodiments of the present disclosure are not restricted to those set forth herein. The above and other aspects and features of embodiments of the present disclosure will become more apparent to one of ordinary skill in the art to which the present disclosure pertains by referencing the detailed description of the present disclosure given below.

According to one or more embodiments of the present disclosure, a display device includes: a substrate; a field effect transistor on the substrate; an oxide-based transistor on a layer different from the field effect transistor and connected to the field effect transistor through a contact hole in an insulating layer; and a pixel electrode on the oxide-based transistor.

In one or more embodiments, the field effect transistor includes a metal-oxide-semiconductor field effect transistor (MOSFET).

In one or more embodiments, the substrate includes a silicon substrate.

In one or more embodiments, the field effect transistor includes a driving transistor including a gate electrode connected to a first node, a source electrode connected to a driving voltage line, and a drain electrode connected to a second node.

In one or more embodiments, the field effect transistor further includes an emission control transistor including a gate electrode connected to an emission control line, a source electrode connected to the second node, and a drain electrode connected to the pixel electrode.

In one or more embodiments, the field effect transistor further includes an initialization transistor including a gate electrode connected to a third gate line, a source electrode connected to the pixel electrode, and a drain electrode connected to a ground.

In one or more embodiments, the oxide-based transistor includes a switching transistor including a gate electrode connected to a first gate line, a drain electrode connected to a data line, and a source electrode connected to the first node.

In one or more embodiments, the oxide-based transistor further a compensation transistor including a gate electrode connected to a second gate line, a drain electrode connected to the first node, and a source electrode connected to the second node.

In one or more embodiments, further including a first capacitor connected between the driving voltage line and the first node.

In one or more embodiments, further a second capacitor connected between the source electrode of the switching transistor and the first node.

In one or more embodiments, the first capacitor and the second capacitor are on the oxide-based transistor.

In one or more embodiments, the driving transistor includes a dual gate transistor.

In one or more embodiments, the field effect transistor includes a P-type transistor.

In one or more embodiments, the oxide-based transistor includes an N-type transistor.

In one or more embodiments, an active layer of the oxide-based transistor includes indium-gallium-zinc oxide (IGZO) or indium-gallium-zinc-tin oxide (IGZTO).

In one or more embodiments, the oxide-based transistor is located farther from the substrate than the field effect transistor is.

In one or more embodiments, the pixel electrode is connected to the field effect transistor.

In one or more embodiments, the field effect transistor is a double gate transistor.

In one or more embodiments, the field effect transistor overlaps the oxide-based transistor.

In the display device according to the present disclosure, the switching transistor and the compensation transistor include an oxide-based active layer (or a semiconductor layer). Accordingly, leakage current (e.g., leakage current in a turn-on state) of the switching transistor and the compensation transistor may be reduced or minimized. Accordingly, voltage fluctuations of a gate node to which the gate electrode of the driving transistor, the drain electrode of the switching transistor, and the drain electrode of the compensation transistor are commonly connected may be reduced or minimized, so that the image quality of the display device may be improved.

The effects, aspects, and features of the present disclosure are not limited to the aforementioned effects, aspects, and features, and various other effects, aspects, and features are included in the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view showing a display device according to one or more embodiments;

FIG. 2 is a cross-sectional view illustrating a display device according to one or more embodiments;

FIG. 3 is a plan view illustrating a display unit of a display device according to one or more embodiments;

FIG. 4 is a block diagram illustrating a display panel and a display driver according to one or more embodiments;

FIG. 5 is a circuit diagram of one pixel of a display device according to one or more embodiments;

FIG. 6 is a timing diagram of the first to third gate signals GW, GC, and GR, the emission control signal EM, and the data signal DATA of FIG. 5;

FIG. 7 is a circuit diagram of one pixel of a display device according to one or more embodiments;

FIG. 8 is a plan view of transistors of a pixel array according to one or more embodiments;

FIG. 9 illustrates a first pattern layer of a pixel according to one or more embodiments;

FIG. 10 illustrates a second pattern layer of a pixel according to one or more embodiments;

FIG. 11 shows a third pattern layer and a first type contact hole of a pixel according to one or more embodiments;

FIG. 12 illustrates a fourth pattern layer and a second type contact hole of a pixel according to one or more embodiments;

FIG. 13 shows a fifth pattern layer and a third type contact hole of a pixel according to one or more embodiments;

FIG. 14 illustrates a sixth pattern layer of a pixel according to one or more embodiments;

FIG. 15 shows a seventh pattern layer and a fourth type contact hole of a pixel according to one or more embodiments;

FIG. 16 illustrates an eighth pattern layer and a fifth type contact hole of a pixel according to one or more embodiments;

FIG. 17 shows a ninth pattern layer and a sixth type contact hole of a pixel according to one or more embodiments;

FIG. 18 illustrates a tenth pattern layer and a seventh type contact hole of a pixel according to one or more embodiments;

FIG. 19 shows an eleventh pattern layer and an eighth type contact hole of a pixel according to one or more embodiments;

FIG. 20 illustrates the first pattern layer of FIG. 9 and the second pattern layer of FIG. 10;

FIG. 21 shows the first pattern layer of FIG. 9, the second pattern layer of FIG. 10, and the third pattern layer and the first type contact hole of FIG. 11;

FIG. 22 illustrates the first pattern layer of FIG. 9, the second pattern layer of FIG. 10, the third pattern layer and the first type contact hole of FIG. 11, and the fourth pattern layer and the second type contact hole of FIG. 12;

FIG. 23 shows the fourth pattern layer of FIG. 12, and the fifth pattern layer and the third type contact hole of FIG. 13;

FIG. 24 illustrates the fifth pattern layer of FIG. 13 and the sixth pattern layer of FIG. 14;

FIG. 25 shows the sixth pattern layer of FIG. 14 and the seventh pattern layer of FIG. 15;

FIG. 26 illustrates the fifth pattern layer of FIG. 13, the sixth pattern layer of FIG. 14, and the seventh pattern layer and the fourth type contact hole of FIG. 15;

FIG. 27 shows the seventh pattern layer of FIG. 15, and the eighth pattern layer and the fifth type contact hole of FIG. 16;

FIG. 28 illustrates the tenth pattern layer of FIG. 18, and the eleventh pattern layer and the eighth type contact hole of FIG. 19;

FIGS. 29A and 29B are cross-sectional views taken along the line I-I′ of FIGS. 8 to 28;

FIG. 30 is a cross-sectional view illustrating a structure of a display element according to one or more embodiments;

FIGS. 31 to 34 are cross-sectional views illustrating a structure of a light emitting element LEL according to one or more embodiments;

FIG. 35 is a cross-sectional view illustrating an example of the organic light emitting diode of FIG. 33;

FIG. 36 is a cross-sectional view illustrating an example of the organic light emitting diode of FIG. 34;

FIG. 37 is a cross-sectional view illustrating a structure of a pixel of a display device according to one or more embodiments;

FIG. 38 is an example diagram illustrating a virtual reality device including a display device according to one or more embodiments; and

FIGS. 39 and 40 are diagrams for explaining the effects of the present disclosure.

### DETAILED DESCRIPTION

Hereinafter, embodiments will be described in detail with reference to the accompanying drawings.

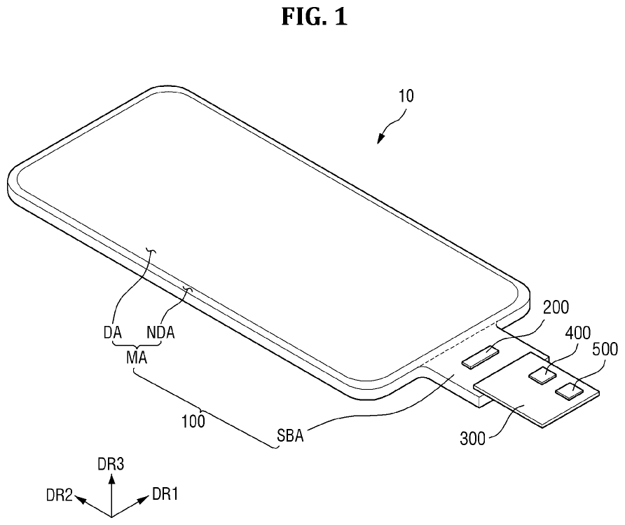

FIG. 1 is a perspective view showing a display device according to one or

more embodiments.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

The display device 10 may have a planar shape similar to a quadrilateral shape. For example, the display device 10 may have a planar shape similar to a quadrilateral shape having a short side in the first direction DR1 and a long side in the second direction DR2. A corner where the short side in the first direction DR1 and the long side in the second direction DR2 meet may be right-angled or rounded with a suitable curvature (e.g., a predetermined curvature). The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA.

The main region MA may include the display area DA including pixels configured to display an image and the non-display area NDA disposed around the display area DA along an edge or periphery of the display area DA. The display area DA may emit light from a plurality of emission areas or a plurality of opening areas. For example, the display panel 100 may include a pixel circuit including switching elements, a pixel defining layer defining an emission area or an opening area, and a self-light emitting element LEL.

For example, the self-light emitting element LEL may include at least one of an organic light emitting diode (LED) including an organic light emitting layer, a quantum dot LED including a quantum dot light emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a gate driver that supplies gate signals to the gate lines, and fan-out lines that connect the display driver 200 to the display area DA.

The sub-region SBA may extend from one side of the main region MA. The sub-region SBA may include a flexible material which can be bent, folded, and/or rolled. For example, when the sub-region SBA is bent, the sub-region SBA may overlap the main region MA in a thickness direction (e.g., a third direction DR3, e.g., a thickness direction of a substrate SUB of a display device 10). The sub-region SBA may include the display driver 200 and the pad portion connected to the circuit board 300. Optionally, the sub-region SBA may be omitted, and the display driver and the pad unit may be arranged in the non-display area NDA.

The display driver 200 may output signals and voltages for driving the display panel 100. The display driver 200 may supply data voltages to data lines DL. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, and/or an ultrasonic bonding method. For example, the display driver 200 may be disposed in the sub-region SBA, and may overlap the main region MA in the thickness direction (third direction DR3) by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to a pad portion of the display panel 100. The circuit board 300 may be a flexible printed circuit board, a printed circuit board, or a flexible film such as a chip on film.

A touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a suitable frequency (e.g., a predetermined frequency). The touch driver 400 may calculate whether an input is made and input coordinates based on an amount of change in capacitance between the plurality of touch electrodes. The touch driver 400 may be formed of an integrated circuit (IC).

The power supply unit 500 may be disposed on the circuit board 300 to supply a power voltage to the display driver 200 and the display panel 100. The power supply unit 500 may generate a driving voltage to supply to a driving voltage line VDL, and may generate a common voltage to supply to a common electrode that is common to the light emitting elements LEL of a plurality of pixels. For example, the driving voltage may be a high potential voltage for driving the light emitting element LEL, and the common voltage may be a low potential voltage for driving the light emitting element LEL.

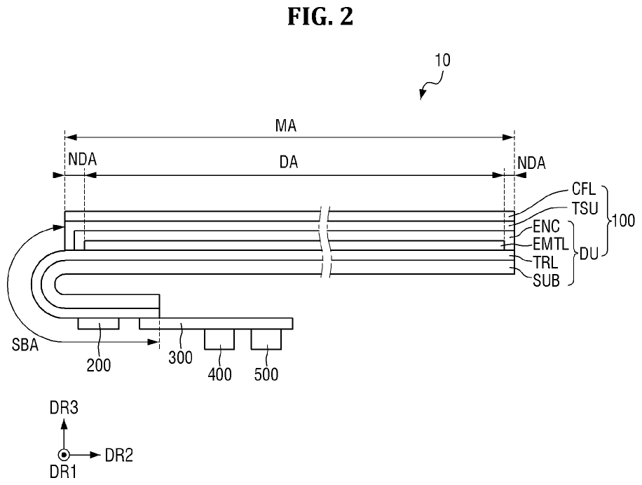

FIG. 2 is a cross-sectional view illustrating a display device according to one or more embodiments.

Referring to FIG. 2, the display panel 100 may include a display unit DU, a touch sensing unit TSU, and a color filter layer CFL. The display unit DU may include a substrate SUB, a transistor layer TRL, a light emitting element layer EMTL, and an encapsulation layer ENC.

The substrate SUB may be a base substrate or a base member. The substrate SUB may be a flexible substrate which can be bent, folded or rolled. For example, the substrate SUB may include a polymer resin such as polyimide (Pl), but is not limited thereto. For another example, the substrate SUB may include a glass material or a metal material.

The transistor layer TRL may be disposed on the substrate SUB. The transistor layer TRL may include a plurality of transistors constituting a pixel circuit of pixels. The transistor layer TRL may further include the gate lines, the data lines DL, the power lines, gate control lines, the fan-out lines that connect the display driver to the data lines DL, and the lead lines that connect the display driver 200 to the pad portion. Each of the transistors may include a semiconductor region, a source electrode, a drain electrode, and a gate electrode. For example, when the gate driver is formed on one side of the non-display area NDA of the display panel 100, the gate driver may include transistors.

The transistor layer TRL may be disposed in the display area DA, the non-display area NDA, and the sub-region SBA. Transistors, gate lines, data lines DL, and power lines of each of the pixels of the transistor layer TRL may be disposed in the display area DA. Gate control lines and fan-out lines of the transistor layer TRL may be disposed in the non-display area NDA. The lead lines of the transistor layer TRL may be disposed in the sub-region SBA.

The light emitting element layer EMTL may be disposed on the transistor layer TRL. The light emitting element layer EMTL may include the plurality of light emitting elements LEL in which a pixel electrode, a light emitting layer, and a common electrode are sequentially stacked to emit light, and the pixel defining layer defining the pixels. The plurality of light emitting elements LEL of the light emitting element layer EMTL may be disposed in the display area DA.

For example, the light emitting layer may be an organic light emitting layer including an organic material. The light emitting layer may include a hole transporting layer, an organic light emitting layer, and an electron transporting layer. When the pixel electrode receives a suitable voltage (e.g., a predetermined voltage) through the transistor of the transistor layer TRL and the common electrode receives the cathode voltage, holes and electrons may be transferred to the organic light emitting layer through the hole transporting layer and the electron transporting layer, respectively and may be combined with each other to emit light in the organic light emitting layer. For example, the pixel electrode may be an anode electrode, and the common electrode may be a cathode electrode, but the present disclosure is not limited thereto.

For another example, the plurality of light emitting elements LEL may include a quantum dot light emitting diode including a quantum dot light emitting layer, an inorganic light emitting diode including an inorganic semiconductor, or a micro light emitting diode.

The encapsulation layer ENC may cover the top surface and the side surface of the light emitting element layer EMTL, and may protect the light emitting element layer EMTL. The encapsulation layer ENC may include at least one inorganic layer and at least one organic layer for encapsulating the light emitting element layer EMTL.

The touch sensing unit TSU may be disposed on the encapsulation layer ENC. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method.

For another example, the touch sensing unit TSU may be disposed on a separate substrate disposed on the display unit DU. In this case, the substrate supporting the touch sensing unit TSU may be a base member that encapsulates the display unit DU.

The plurality of touch electrodes of the touch sensing unit TSU may be disposed in a touch sensor area overlapping the display area DA. The touch lines of the touch sensing unit TSU may be disposed in a touch peripheral area that overlaps the non-display area NDA.

The color filter layer CFL may be disposed on the touch sensing unit TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Because the color filter layer CFL is directly disposed on the touch sensing unit TSU, the display device 10 may not require a separate substrate for the color filter layer CFL. Therefore, the thickness of the display device 10 may be relatively reduced.

The sub-region SBA of the display panel 100 may extend from one side of the main region MA. The sub-region SBA may include a flexible material that can be bent, folded, and/or rolled. For example, when the sub-region SBA is bent, the sub-region SBA may overlap the main region MA in the thickness direction (e.g., the third direction DR3). The sub-region SBA may include the display driver 200 and the pad unit electrically connected to the circuit board 300.

When the sub-region SBA is bent, a protective layer may be further disposed on the bent portion of the sub-region SBA.

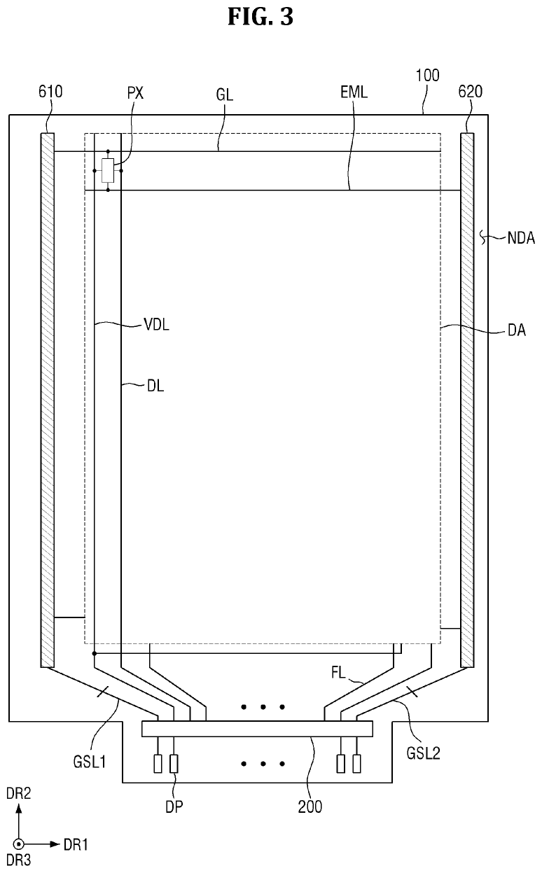

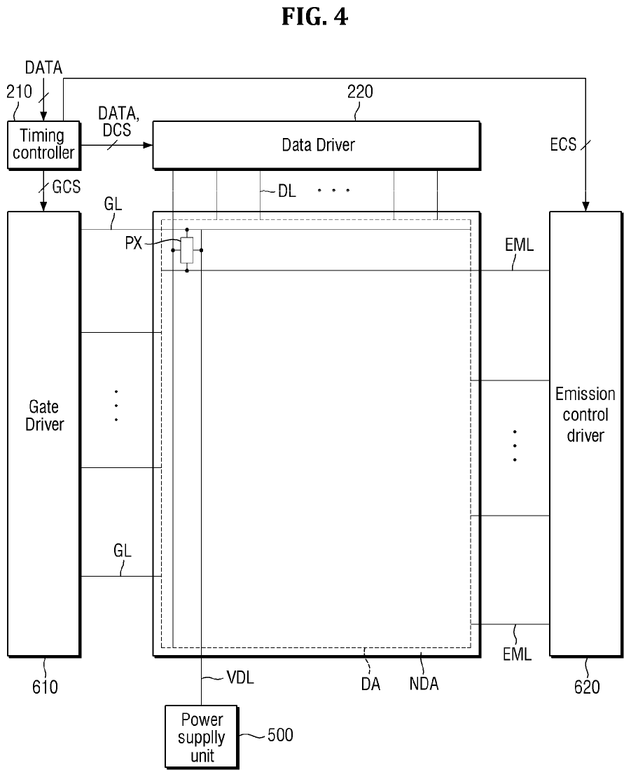

FIG. 3 is a plan view illustrating a display unit of a display device according to one or more embodiments. FIG. 4 is a block diagram illustrating a display panel and a display driver according to one or more embodiments.

Referring to FIGS. 3 and 4, the display panel 100 may include the display area DA and the non-display area NDA.

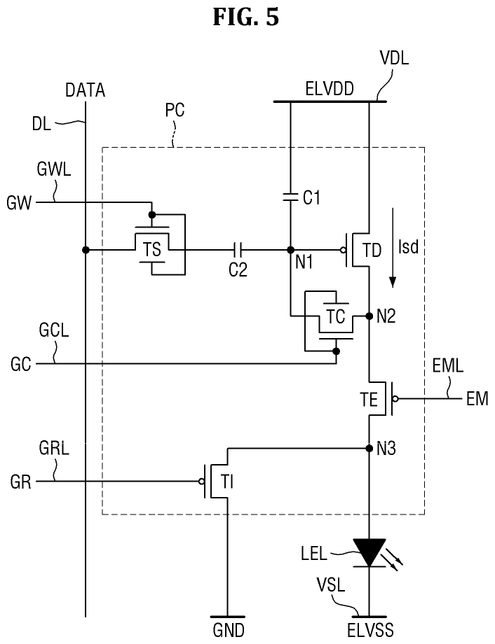

The display area DA may include a plurality of pixels PX, and a plurality of driving voltage lines VDL, a plurality of common voltage lines VSL (see FIG. 5), a plurality of gate lines GL, a plurality of emission control lines EML, and a plurality of data lines DL connected to the plurality of pixels PX.

Each of the plurality of pixels PX may be connected to the gate line GL, the data line DL, the emission control line EML, the driving voltage line VDL, and the common voltage line VSL. Each of the pixels PX may include at least one transistor, the light emitting element LEL, and a capacitor.

Each of the plurality of gate lines GL may extend in the first direction DR1 and may be spaced from each other in the second direction DR2 intersecting the first direction DR1. The gate lines GL may be arranged along the second direction DR2. The gate lines GL may sequentially supply gate signals to the plurality of pixels PX.

The emission control lines EML may extend in the first direction DR1 and may be spaced from each other in the second direction DR2. The emission control line EML may be arranged along the second direction DR2. The emission control lines EML may sequentially supply an emission control signal EM to the plurality of pixels PX.

The data lines DL may extend in the second direction DR2 and may be spaced from each other in the first direction DR1. The data lines DL may be arranged along the first direction DR1. The data lines DL may supply data voltages to the plurality of pixels PX. The data voltage may determine the luminance of each of the pixels PX.

The driving voltage lines VDL may extend in the second direction DR2 and may be spaced from each other in the first direction DR1. The driving voltage lines VDL may be arranged along the first direction DR1. The driving voltage lines VDL may supply a driving voltage to the plurality of pixels PX. The driving voltage may be a high potential voltage for driving the light emitting element LEL of the pixels PX.

The non-display area NDA may be around (e.g., may surround) the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal EM received from the display driver 200 to the emission control driver 620.

The sub-region SBA may extend from one side of the non-display area NDA. The sub-region SBA may include the display driver 200 and the pad portion DP. The pad portion DP may be disposed closer to one edge of the sub-region SBA than the display driver 200. The pad portion DP may be electrically connected to the circuit board 300 through an anisotropic conductive film ACF.

The display driver 200 may include a timing controller 210 and a data driver 220.

The timing controller 210 may receive a digital video data signal DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal EM to control the operation timing of the emission control driver 620. The timing controller 210 may supply the gate control signal GCS to the gate driver 610 through the first gate control line GSL1. The timing controller 210 may supply the emission control signal EM to the emission control driver 620 through the second gate control line GSL2. The timing controller 210 may supply the digital video data signal DATA and the data control signal DCS to the data driver 220.

The data driver 220 may convert the digital video data signal DATA into analog data voltages and supply them to the data lines DL through the fan-out lines FL. The gate signals of the gate driver 610 may select the pixels PX to which the data voltage is supplied, and the selected pixels PX may receive the data voltage through the data lines DL.

The power supply unit 500 may be disposed on the circuit board 300 to supply a power voltage to the display driver 200 and the display panel 100. The power supply unit 500 may generate a driving voltage to supply to a driving voltage line VDL, and may generate a common voltage to supply to a common electrode that is common to the light emitting elements LEL of a plurality of pixels.

The gate driver 610 may be disposed at one external side of the display area DA or at one side of the non-display area NDA. The emission control driver 620 may be disposed at the other external side of the display area DA or at the other side of the non-display area NDA. However, the present disclosure is not limited thereto. As another example, the gate driver 610 and the emission control driver 620 may be disposed at any one of one side and the other side of the non-display area NDA.

The gate driver 610 may include a plurality of transistors for generating gate signals based on the gate control signal GCS. The emission control driver 620 may include a plurality of transistors for generating emission control signals EM based on the emission control signal EM. For example, the transistors of the gate driver 610 and the transistors of the emission control driver 620 may be formed on the same layer as the transistors of each of the pixels PX. The gate driver 610 may supply the gate signals to the gate lines GL, and the emission control driver 620 may supply the emission control signals EM to the emission control lines EML.

FIG. 5 is a circuit diagram of one pixel of a display device according to one or more embodiments.

The pixel PX may be connected to a first gate line GWL, a second gate line GCL, a third gate line GRL, the emission control line EML, the data line DL, the driving voltage line VDL, the common voltage line VSL. Here, the common voltage line VSL may be connected to the common electrode (e.g., cathode electrode) of the light emitting element LEL.

The pixel PX may include a pixel circuit PC and the light emitting element LEL. The pixel circuit PC may include a driving transistor TD, a switching transistor TS, a compensation transistor TC, an initialization transistor TI, an emission control transistor TE, a first capacitor C1, and a second capacitor C2.

The driving transistor TD may include a gate electrode, a source electrode, and a drain electrode. The driving transistor TD may control a source-drain current (hereinafter referred to as a driving current) according to the data voltage applied to the gate electrode. The driving current (e.g., Isd) flowing through a channel region of the driving transistor TD may be proportional to the square of a difference between the threshold voltage Vth and the voltage Vsg between the source electrode and the gate electrode of the driving transistor TD (Isd=k×(Vsg−Vth)²). Here, k is a proportional coefficient determined by the structure and physical characteristics of the driving transistor TD, Vsg is a source-gate voltage of the driving transistor TD, and Vth is a threshold voltage of the driving transistor TD.

The light emitting element LEL may emit light by receiving the driving current Isd. The emission amount or the luminance of the light emitting element LEL may be proportional to the magnitude of the driving current Isd.

The light emitting element LEL may be an organic light emitting diode including a first electrode, a second electrode, and an organic light emitting layer disposed between the first electrode and the second electrode. For another example, the light emitting element LEL may be an inorganic light emitting element including a first electrode, a second electrode, and an inorganic semiconductor disposed between the first electrode and the second electrode. For still another example, the light emitting element LEL may be a quantum dot light emitting element including a first electrode, a second electrode, and a quantum dot light emitting layer disposed between the first electrode and the second electrode. For still another example, the light emitting element LEL may be a micro light emitting diode.

The first electrode of the light emitting element LEL may be electrically connected to a third node N3. The first electrode of the light emitting element LEL may be connected to the drain electrode of the emission control transistor TE and the source electrode of the initialization transistor TI through the third node N3. The second electrode of the light emitting element LEL may be connected to the common voltage line VSL. The second electrode of the light emitting element LEL may receive a common voltage (e.g., low potential voltage) from the common voltage line VSL.

The switching transistor TS may be turned on by a first gate signal GW of the first gate line GWL to electrically connect the data line DL to a first node N1, which is the gate electrode of the driving transistor TD. As the switching transistor TS is turned on in response to the first gate signal GW, a data voltage Vdat of the data line DL may be supplied to the first node N1. The gate electrode of the switching transistor TS may be electrically connected to the first gate line GWL, the drain electrode thereof may be electrically connected to the data line DL, and the source electrode thereof may be electrically connected to the first node N1 through the second capacitor C2. In one or more embodiments, in order for the data voltage Vdat to be supplied to the data line DL, the above-described data driver 220 may generate the data voltage Vdat, which is an analog voltage, based on the digital video data signal DATA supplied from the outside, and may supply the generated data voltage Vdat to the data line DL.

The compensation transistor TC may be turned on by a second gate signal GC of the second gate line GCL to electrically connect the first node N1, which is the gate electrode of the driving transistor TD, to a second node N2, which is the drain electrode of the driving transistor TD. The compensation transistor TC may be connected in series between the first node N1 and the second node N2. The gate electrode of the compensation transistor TC may be electrically connected to the second gate line GCL, the drain electrode thereof may be electrically connected to the first node N1, and the source electrode thereof may be electrically connected to the second node N2.

The initialization transistor TI may be turned on by a third gate signal GR of the third gate line GRL to electrically connect the ground to the third node N3 which is the first electrode of the light emitting element LEL. The initialization transistor TI may be connected in series between the ground and the third node N3. The gate electrode of the initialization transistor TI may be electrically connected to the third gate line GRL, the drain electrode thereof may be electrically connected to the ground GND, and the source electrode thereof may be electrically connected to the third node N3.

The emission control transistor TE may be turned on by the emission control signal EM of the emission control line EML to electrically connect the second node N2, which is the drain electrode of the driving transistor TD, to the third node N3, which is the first electrode of the light emitting element LEL. The gate electrode of the emission control transistor TE may be electrically connected to the emission control line EML, the source electrode thereof may be electrically connected to the second node N2, and the drain electrode thereof may be electrically connected to the third node N3.

The first capacitor C1 may be connected between the first node N1, which is the gate electrode of the driving transistor TD, and the source electrode of the driving transistor TD (or driving voltage line VDL). The first electrode of the first capacitor C1 may be connected to the first node N1, and the second electrode of the first capacitor C1 may be connected to the source electrode of the driving transistor TD and the driving voltage line VDL. The first capacitor C1 may store, for example, the threshold voltage Vth of the driving transistor TD.

The second capacitor C2 may be electrically connected between the switching transistor TS and the first node N1 which is the gate electrode of the driving transistor TD. The first electrode of the second capacitor C2 may be electrically connected to the drain electrode of the switching transistor TS, and the second electrode of the second capacitor C2 may be electrically connected to the first node N1. The second capacitor C2 may store, for example, the data voltage Vdat supplied from the data line DL through the switching transistor TS.

When the driving transistor TD and the emission control transistor TE are turned on, a driving current may be supplied to the light emitting element LEL, so that the light emitting element LEL may emit light.

At least one of the driving transistor TD, the switching transistor TS, the compensation transistor TC, the initialization transistor TI, and the emission control transistor TE described above may be a metal-oxide-semiconductor field effect transistor (MOSFET). For example, each of the driving transistor TD, initialization transistor TI, and the emission control transistor TE may be a P-type MOSFET.

At least one of the driving transistor TD, the switching transistor TS, the compensation transistor TC, the initialization transistor TI, or the emission control transistor TE may be an oxide-based transistor. For example, each of the switching transistor TS and the compensation transistor TC may be an N-type oxide-based transistor. In other words, each of the switching transistor TS and compensation transistor TC may include an oxide semiconductor material. Because the oxide semiconductor has high carrier mobility and low leakage current, the voltage drop is not large although the driving time is long. That is, in the case of an oxide semiconductor, because a color change of an image due to a voltage drop is not large even during low-frequency driving, low-frequency driving is possible. Accordingly, a display device preventing the generation of leakage current and having reduced power consumption may be implemented by the switching transistor TS and the compensation transistor TC, each including an oxide semiconductor material. In addition, in the case of using an oxide semiconductor transistor, a crystallization process by excimer laser annealing (ELA) is not required to form a low-temperature polycrystaline silicon (LTPS) semiconductor transistor, and thus the manufacturing cost of the display panel 100 may be reduced, so that it is advantageous for implementation of a large-area display device.

The oxide semiconductor is sensitive to light, so that a fluctuation in current amount and the like may occur due to light from the outside. Accordingly, it may be considered to absorb or reflect light from the outside by positioning a metal layer under the oxide semiconductor. The metal layer positioned under the oxide semiconductor of each of the switching transistor TS and the compensation transistor TC may function as a lower gate electrode (e.g., a counter gate electrode). For example, each of the switching transistor TS and the compensation transistor TC may be double gate transistors having two gate electrodes (e.g., a gate electrode and a counter gate electrode). The gate electrode and the counter gate electrode may be disposed to face (e.g., oppose) each other on different layers. For example, each of the switching transistor TS and the compensation transistor TC is an N-type oxide semiconductor transistor, and the gate electrode and the counter gate electrode of each of the switching transistor TS and the compensation transistor TC may be positioned to face (e.g., oppose) each other with an oxide semiconductor interposed therebetween.

Because the aforementioned switching transistor TS and compensation transistor TC include an oxide-based active layer (or a semiconductor layer), the leakage current (e.g., the leakage current in a turn-on state) of the switching transistor TS and the compensation transistor TC may be reduced or minimized. Accordingly, voltage fluctuations of a gate node (e.g., the first node N1) to which the gate electrode of the driving transistor TD, the drain electrode of the switching transistor TS, and the drain electrode of the compensation transistor TC are commonly connected may be reduced or minimized, so that the image quality of the display device may be improved.

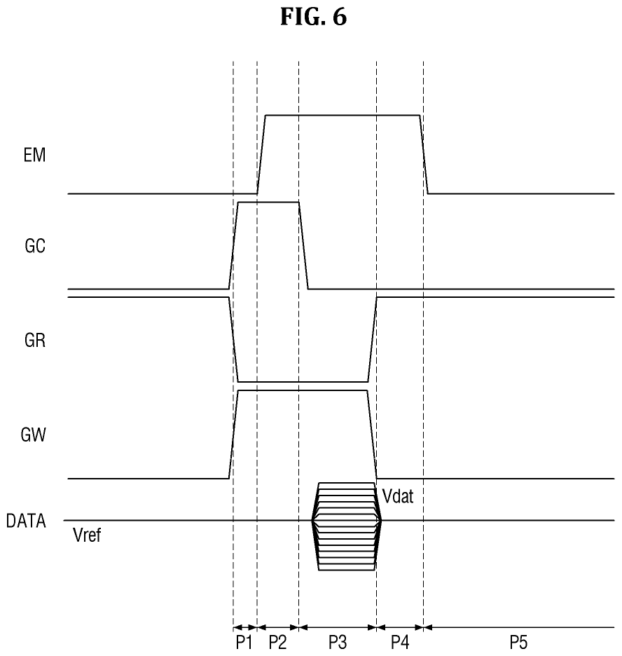

FIG. 6 is a timing diagram of the first to third gate signals GW, GC, and GR, the emission control signal EM, and the data signal DATA of FIG. 5.

As in the example shown in FIG. 6, the display device 10 of the present disclosure may operate based on an initialization period P1, a threshold voltage detection period P2, a data writing period P3, and an emission period P5. Here, the threshold voltage detection period P2 may refer to a period in which the threshold voltage Vth of the driving transistor TD is detected.

The initialization period P1, the threshold voltage detection period P2, the data writing period P3, a margin period P4, and the emission period P5 may be sequentially and cyclically repeated. For example, the threshold voltage detection period P2 may proceed after the initialization period P1, the data writing period P3 may proceed after the threshold voltage detection period P2, the margin period P4 may proceed after the data writing period P3, the emission period P5 may proceed after the margin period P4, and the initialization period P1 may proceed again after the emission period P5. After the initialization period P1, the preceding periods may be repeated again.

The first gate signal GW, the second gate signal GC, the third gate signal GR, and the emission control signal EM may each have an active level or a non-active level for each period. Here, the active level of each signal may mean a voltage at a level capable of turning on a corresponding transistor to which the corresponding signal is applied. In other words, the active level signal may have a value greater than the threshold voltage of the corresponding transistor. For example, when the corresponding transistor is a P-type transistor, the active level of each signal may mean a low level. The non-active level of each signal may mean a voltage at a level capable of turning off a corresponding transistor. In other words, the non-active level signal may have a smaller value than the threshold voltage of the corresponding transistor. For example, when the corresponding transistor is a P-type transistor, the non-active level of each signal may mean a high level. When the corresponding transistor is an N-type transistor, the active level of each signal may mean a high level, and the non-active level of each signal may mean a low level.

During the initialization period P1, the first gate signal GW, the second gate signal GC, the third gate signal GR, and the emission control signal EM may have the active level. In the initialization period P1, the data signal DATA may have the level of an initialization voltage Vref. In other words, the data signal DATA of the initialization period P1 may be the initialization voltage. The initialization voltage may have a smaller value than, for example, the common voltage ELVSS.

Thereafter, during the threshold voltage detection period P2, the first gate signal GW, the second gate signal GC, and the third gate signal GR may have the active level, while the emission control signal EM may have the non-active level. In one or more embodiments, during the threshold voltage detection period P2, the data signal DATA may be maintained at the level of the aforementioned initialization voltage Vref.

Next, during the data writing period P3, the first gate signal GW and the third gate signal GR may have the active level, whereas the second gate signal GC and the emission control signal EM may have the non-active level. During the data writing period P3, the data signal may transition (or change) to the level of the data voltage. In other words, the data signal DATA of the data writing period P3 may be the data voltage Vdat having a value corresponding to a specific grayscale of an image to be displayed.

Thereafter, during the margin period P4, the first gate signal GW, the second gate signal GC, the third gate signal GR, and the emission control signal EM may all have the non-active level. During the margin period P4, the data signal DATA may be maintained at the level of the initialization voltage (e.g., Vref).

Next, during the emission period P5, the emission control signal EM may have the active level, whereas the first to third gate signals GW, GC, and GR may each have the non-active level. In the emission period P5, the data signal DATA may be maintained at the level of the initialization voltage (e.g., Vref).

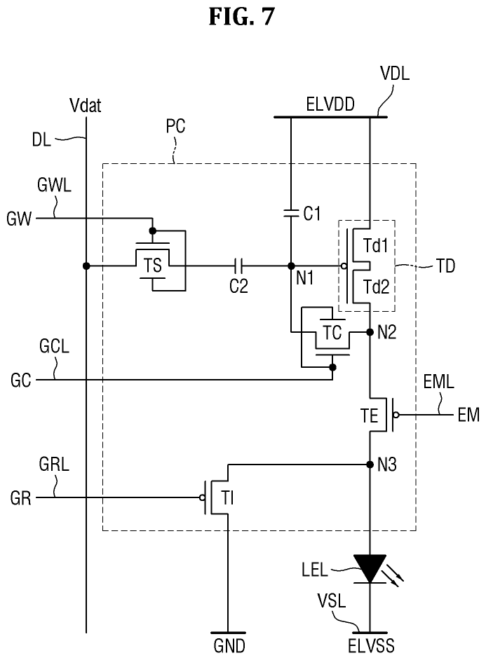

FIG. 7 is a circuit diagram of one pixel of a display device according to one or more embodiments.

The pixel PX of the display device 10 according to the embodiment shown in FIG. 7 is different from the pixel PX of FIG. 5 in that the driving transistor TD is composed of a dual-gate transistor, and thus, the following description will focus on the difference.

As in the example shown in FIG. 7, the driving transistor TD may include a first sub-transistor Td1 and a second sub-transistor Td2 connected in series between the second node N2 and the driving voltage line VDL.

The gate electrode of the first sub-transistor Td1 may be connected to the first node N1, the source electrode of the first sub-transistor Td1 may be connected to the driving voltage line VDL, and the drain electrode of the first sub-transistor Td1 may be connected to the source electrode of the second sub-transistor Td2.

The gate electrode of the second sub-transistor Td2 may be connected to the first node N1, the source electrode of the second sub-transistor Td2 may be connected to the drain electrode of the first sub-transistor Td1, and the drain electrode of the second sub-transistor Td2 may be connected to the second node N2.

The gate electrode of the first sub-transistor Td1 and the gate electrode of the second sub-transistor Td2 may be integrally formed.

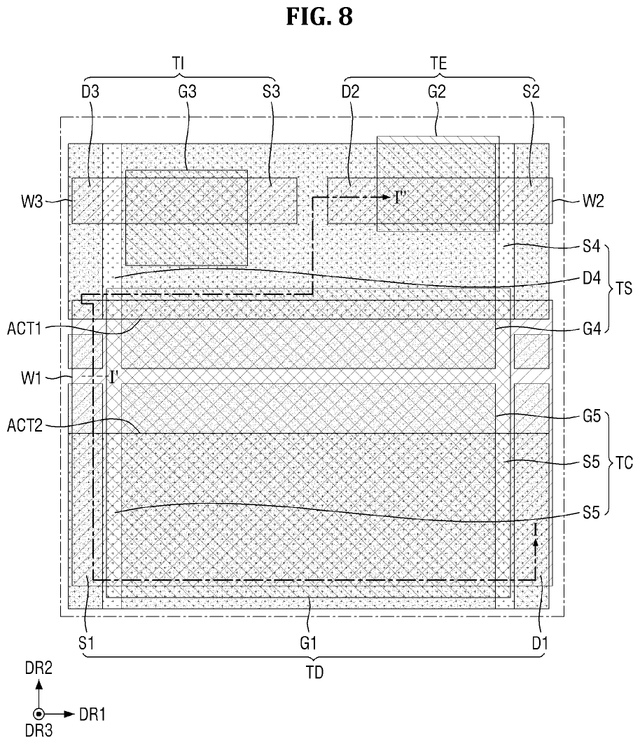

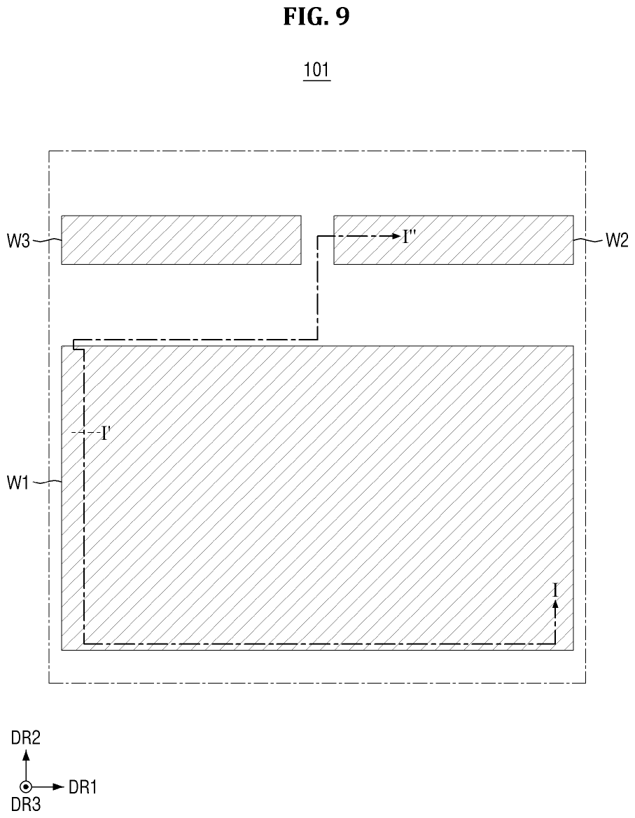

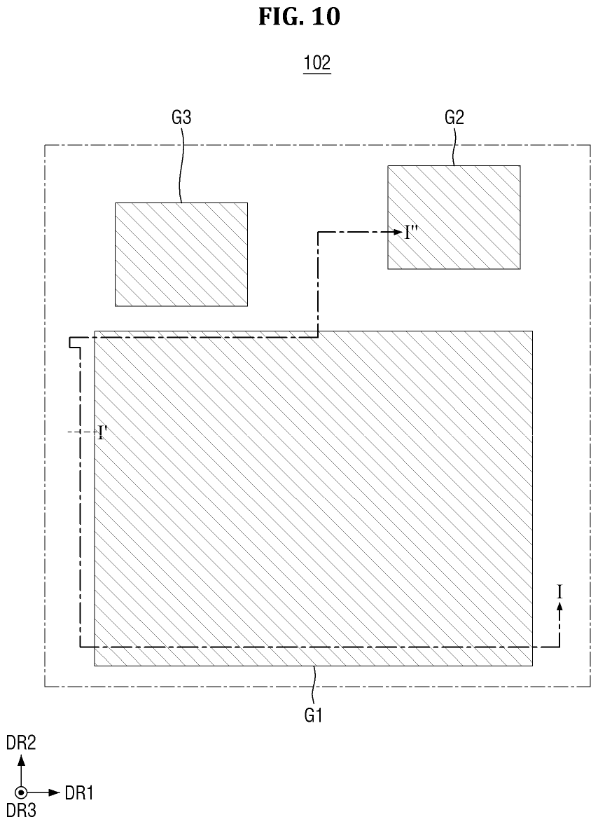

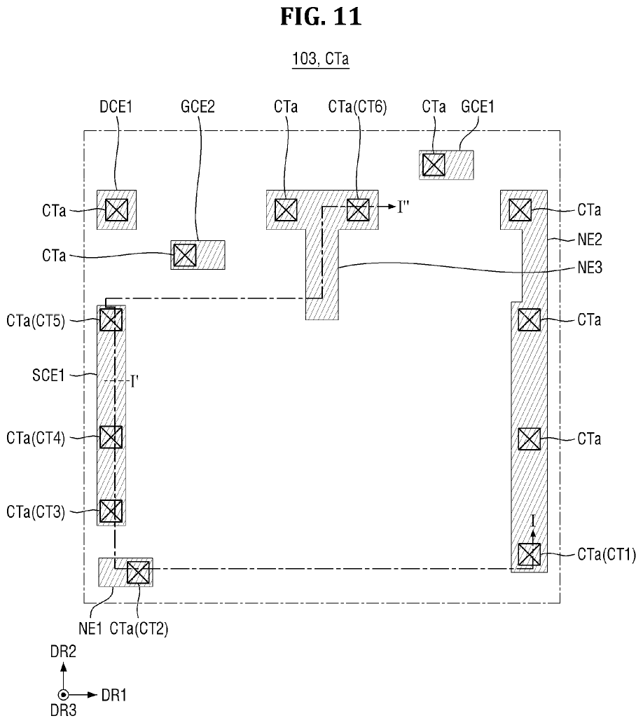

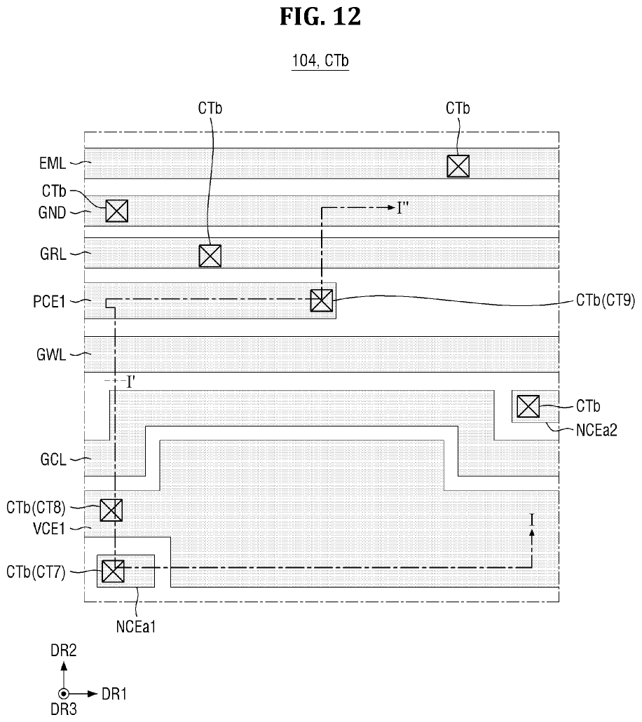

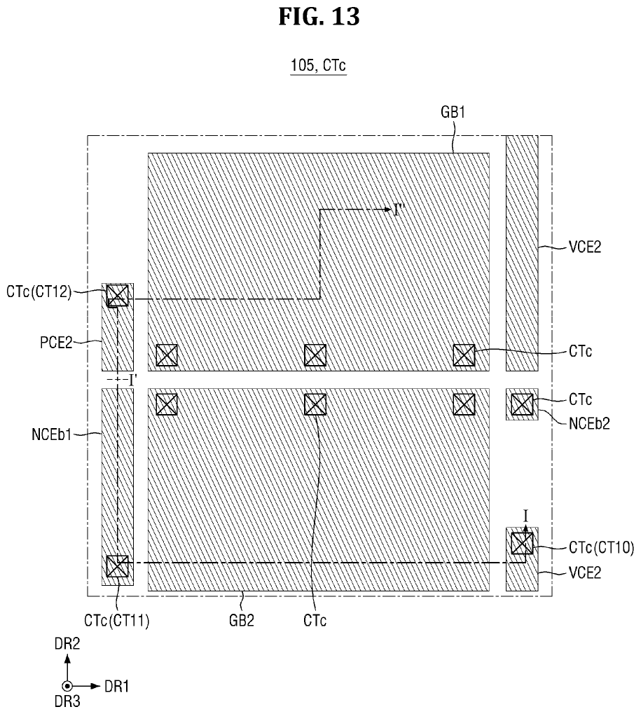

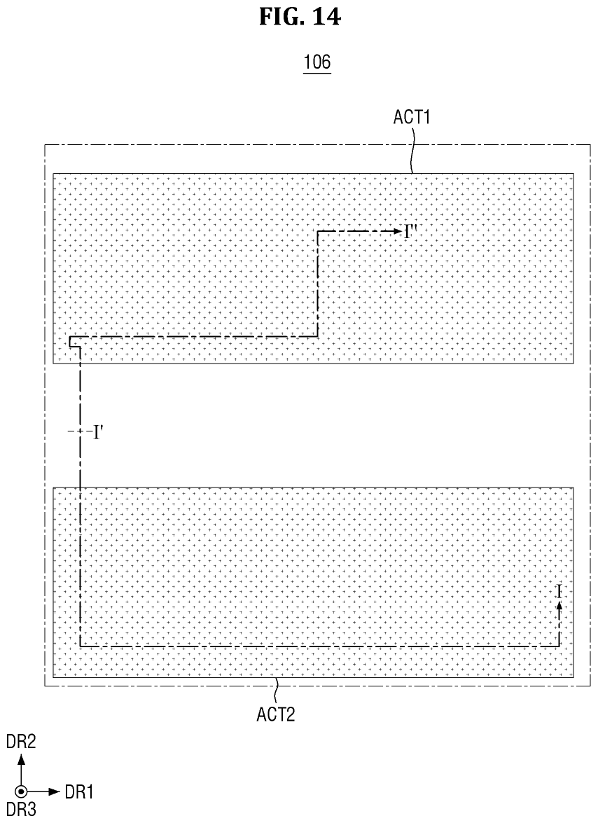

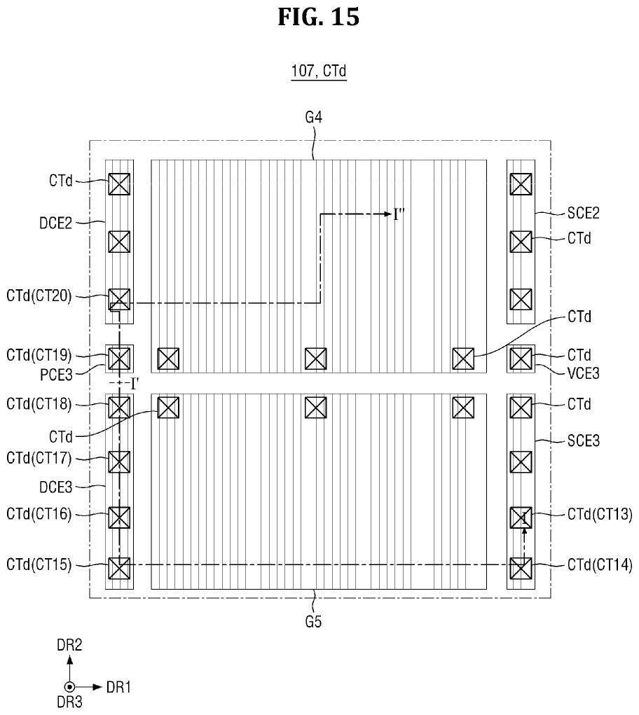

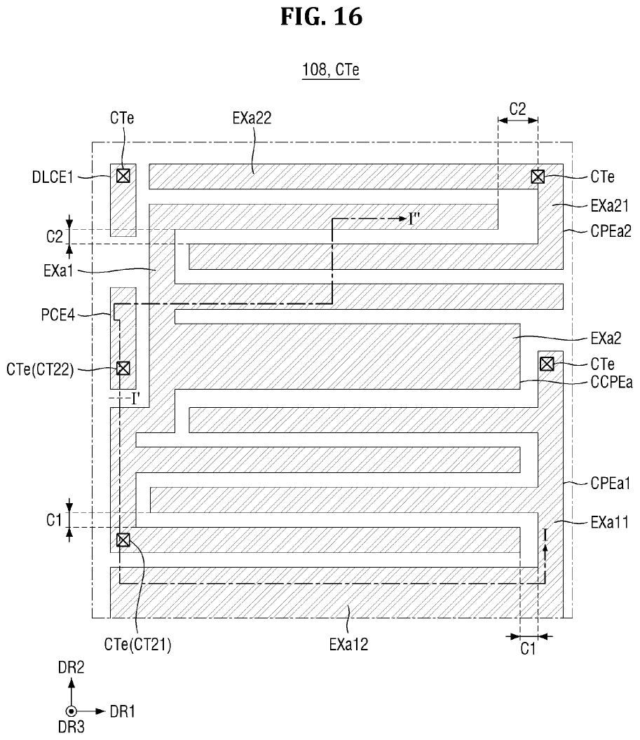

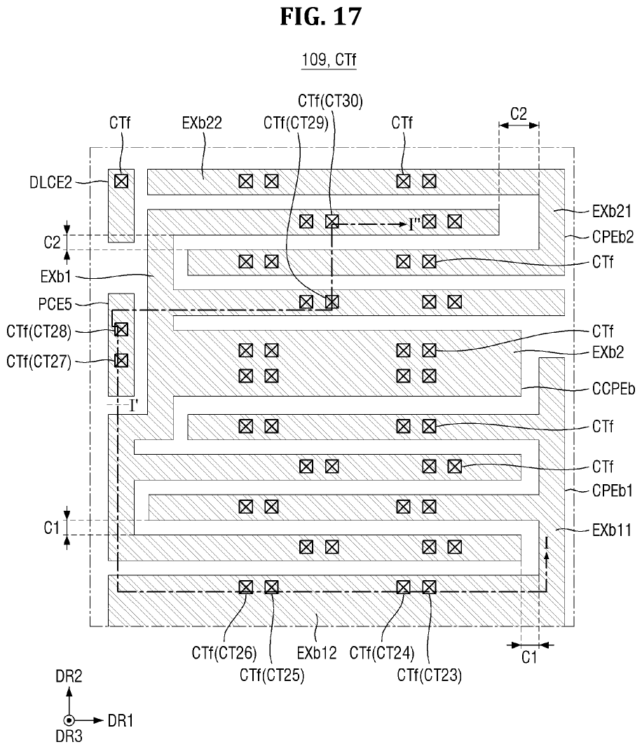

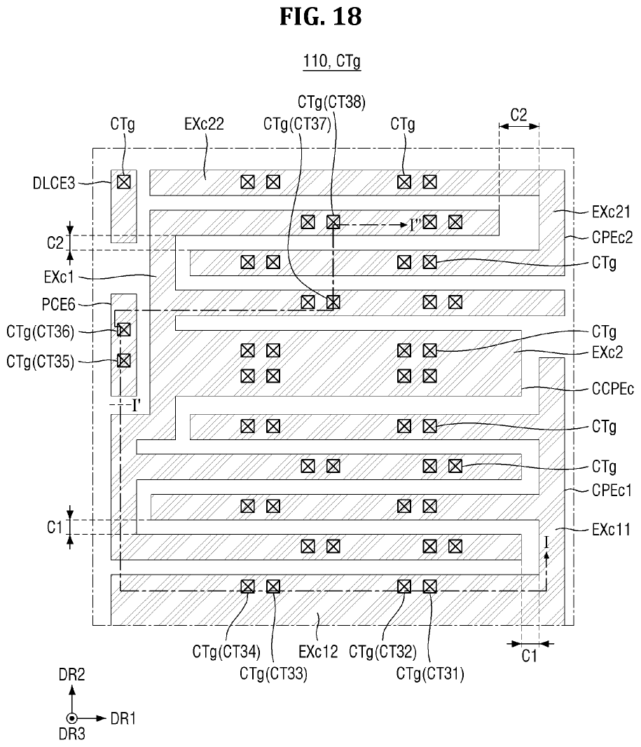

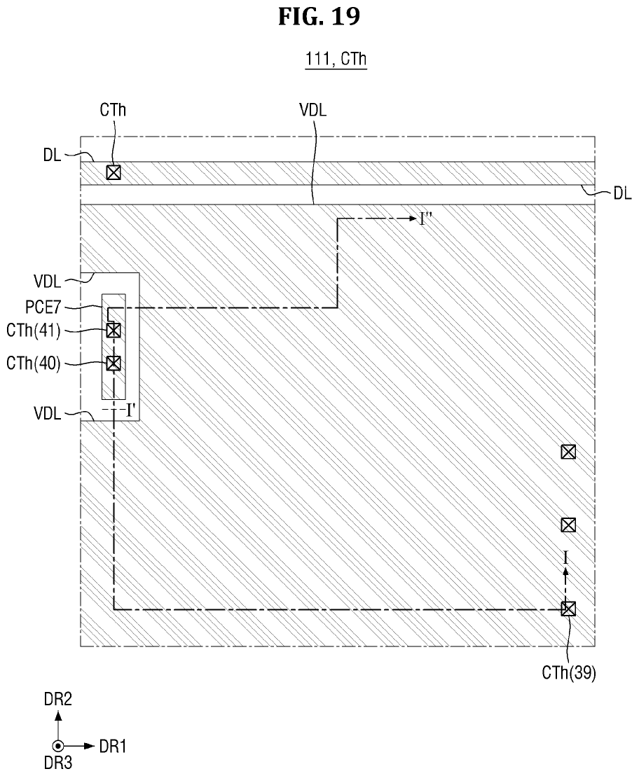

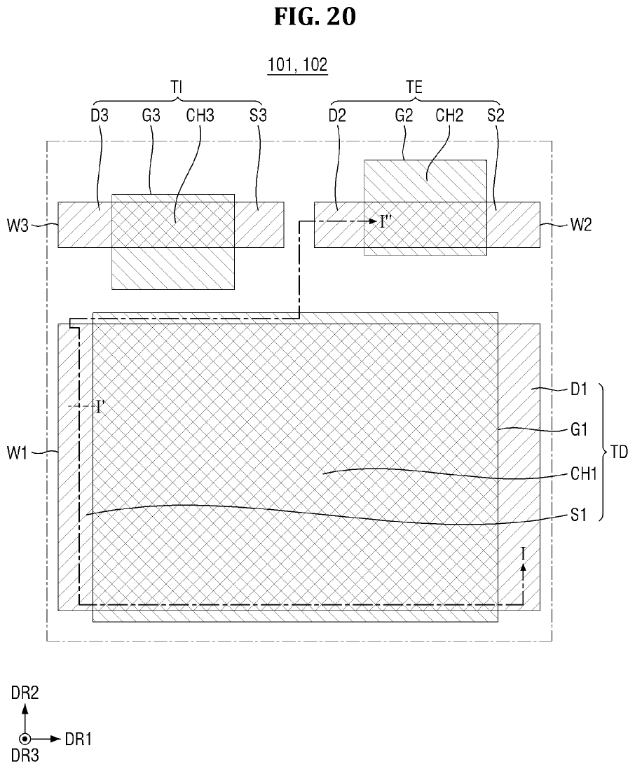

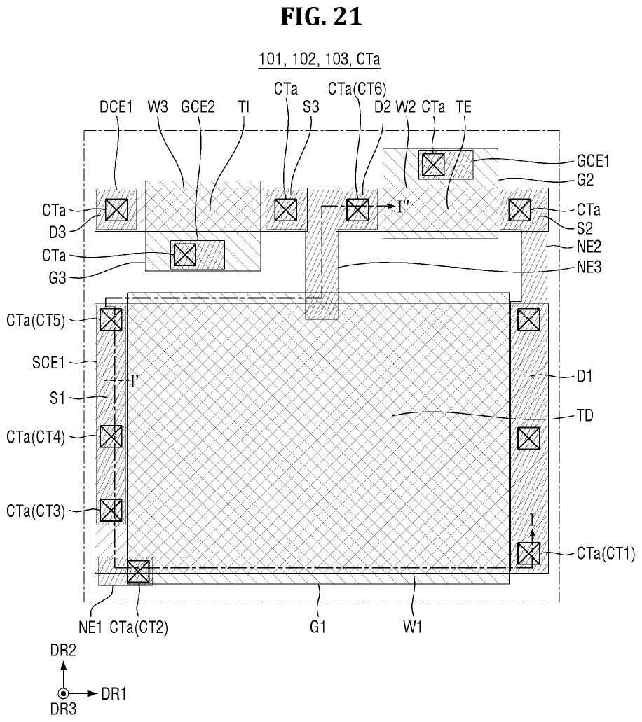

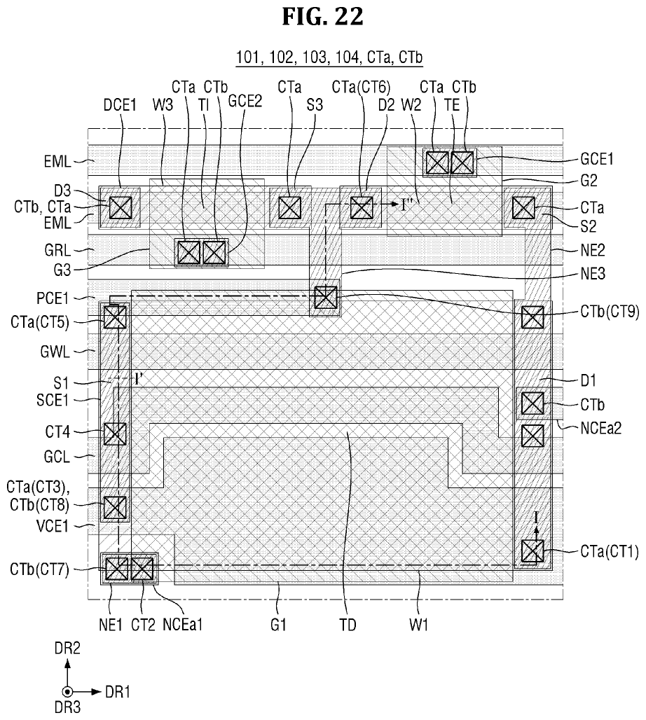

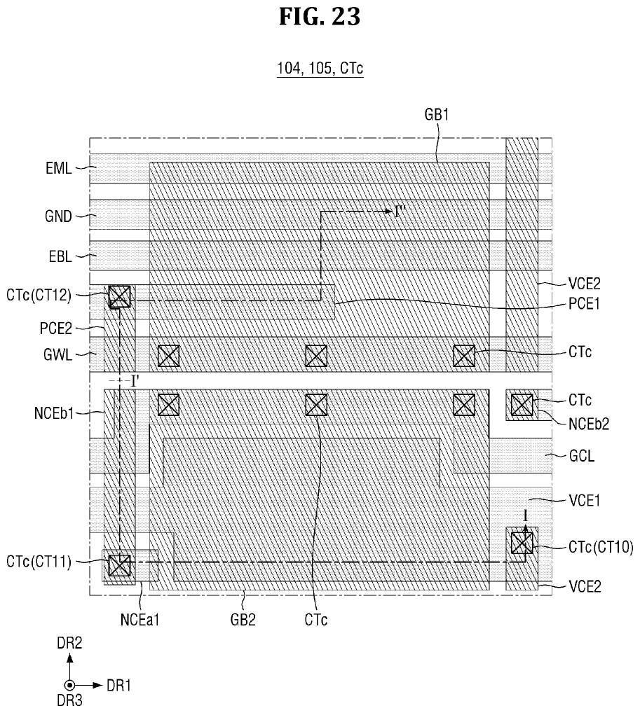

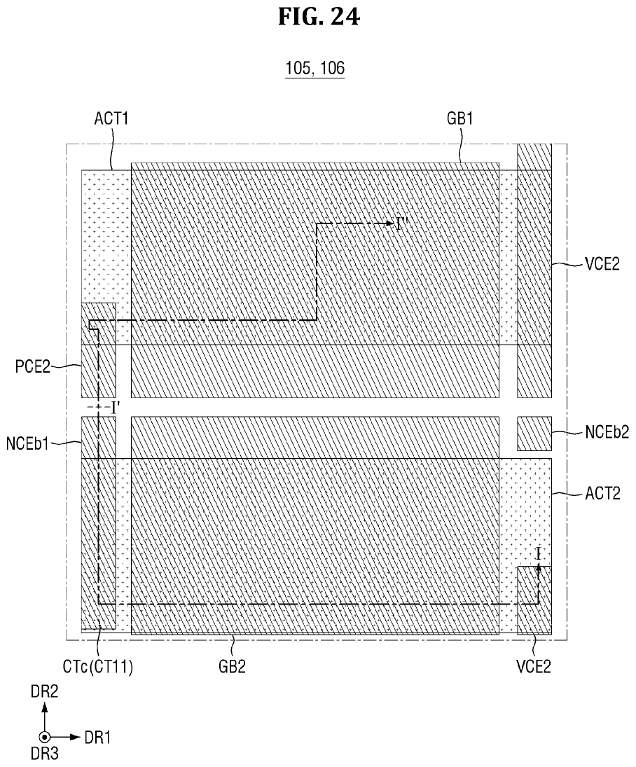

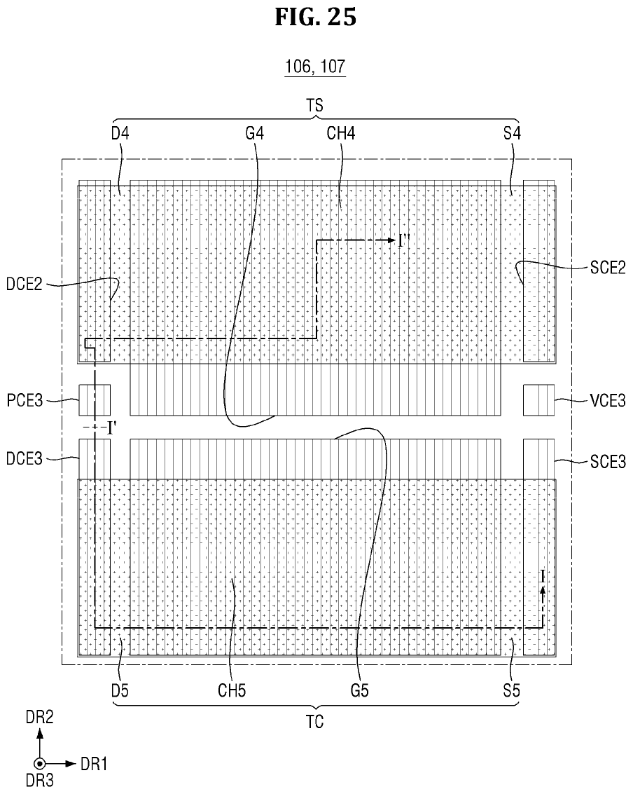

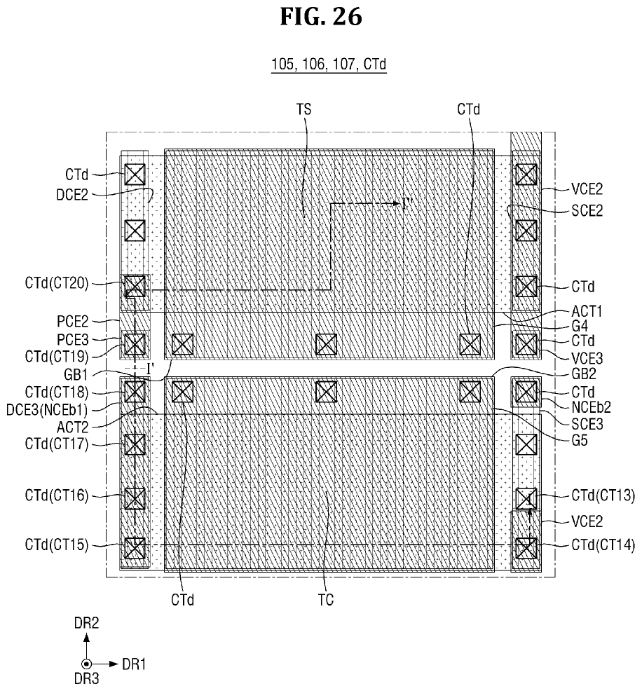

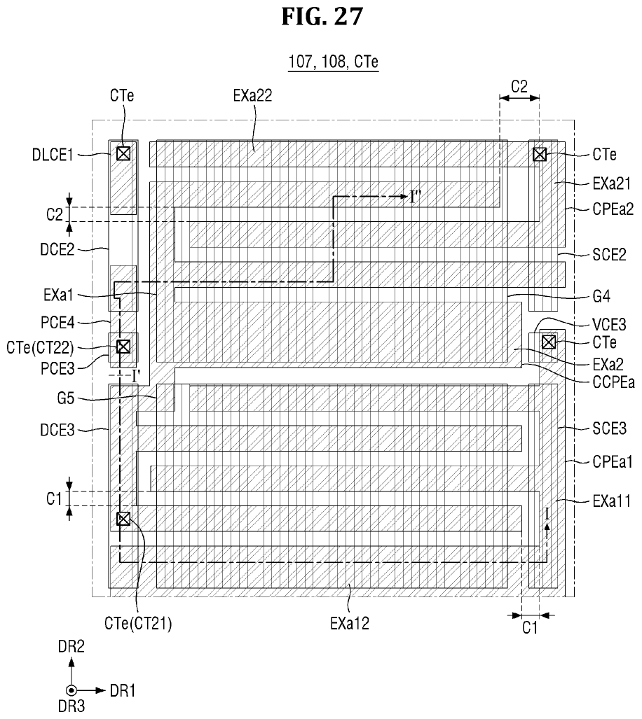

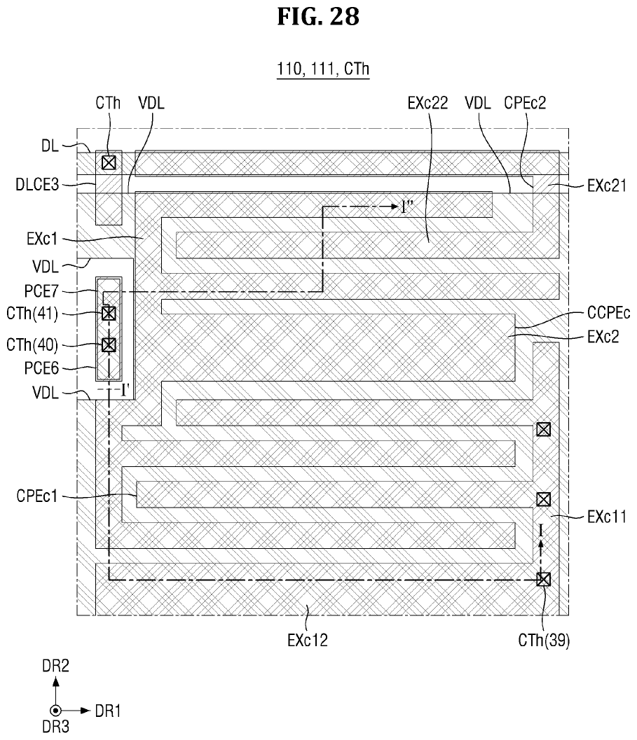

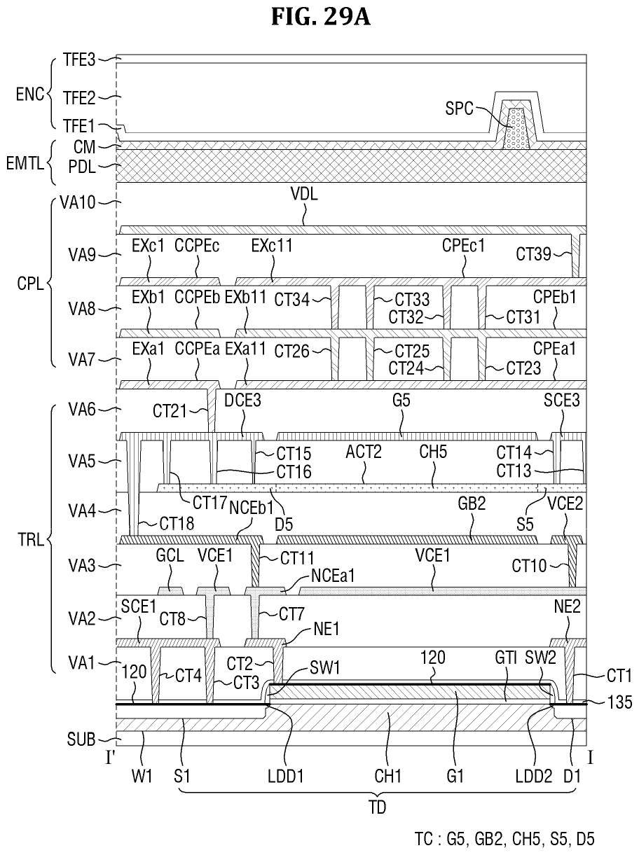

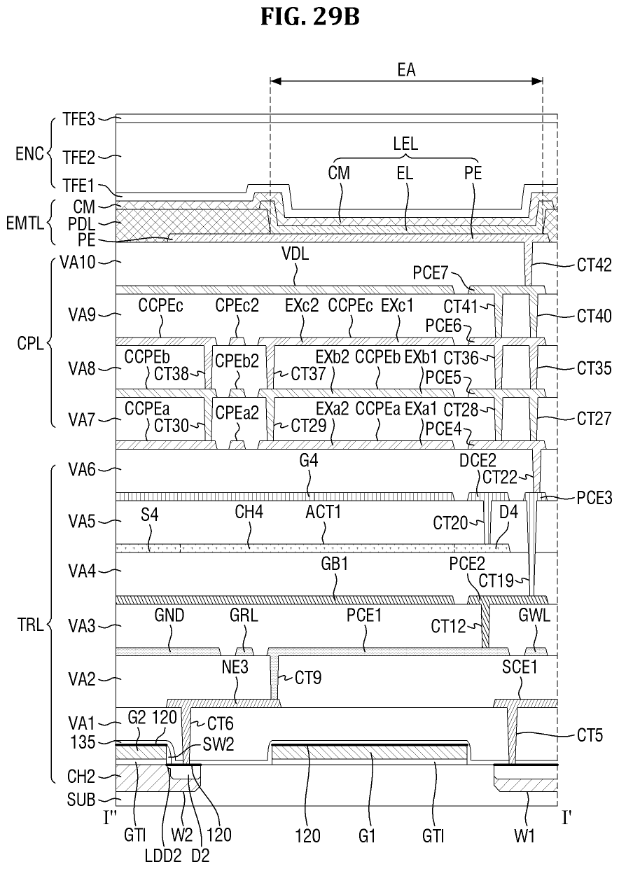

FIG. 8 is a plan view of transistors of a pixel array according to one or more embodiments. FIG. 9 illustrates a first pattern layer 101 of a pixel according to one or more embodiments. FIG. 10 illustrates a second pattern layer 102 of a pixel according to one or more embodiments. FIG. 11 shows a third pattern layer 103 and a first type contact hole CTa of a pixel according to one or more embodiments. FIG. illustrates a fourth pattern layer 104 and a second type contact hole CTb of a pixel according to one or more embodiments. FIG. 13 shows a fifth pattern layer 105 and a third type contact hole CTc of a pixel according to one or more embodiments. FIG. illustrates a sixth pattern layer 106 of a pixel according to one or more embodiments. FIG. 15 shows a seventh pattern layer 107 and a fourth type contact hole CTd of a pixel according to one or more embodiments. FIG. 16 illustrates an eighth pattern layer 108 and a fifth type contact hole CTe of a pixel according to one or more embodiments. FIG. 17 shows a ninth pattern layer 109 and a sixth type contact hole CTf of a pixel according to one or more embodiments. FIG. 18 illustrates a tenth pattern layer 110 and a seventh type contact hole CTg of a pixel according to one or more embodiments. FIG. 19 shows an eleventh pattern layer and an eighth type contact hole CTh of a pixel according to one or more embodiments. FIG. 20 illustrates the first pattern layer 101 of FIG. 9 and the second pattern layer 102 of FIG. 10. FIG. 21 shows the first pattern layer 101 of FIG. 9, the second pattern layer 102 of FIG. 10, and the third pattern layer 103 and the first type contact hole CTa of FIG. 11. FIG. 22 illustrates the first pattern layer 101 of FIG. 9, the second pattern layer 102 of FIG. 10, the third pattern layer 103 and the first type contact hole CTa of FIG. 11, and the fourth pattern layer 104 and the second type contact hole CTb of FIG. 12. FIG. 23 shows the fourth pattern layer 104 of FIG. 12, and the fifth pattern layer 105 and the third type contact hole CTc of FIG. 13. FIG. 24 illustrates the fifth pattern layer 105 of FIG. 13 and the sixth pattern layer 106 of FIG. 14. FIG. 25 shows the sixth pattern layer 106 of FIG. 14 and the seventh pattern layer 107 of FIG. 15. FIG. 26 illustrates the fifth pattern layer 105 of FIG. 13, the sixth pattern layer 106 of FIG. 14, and the seventh pattern layer 107 and the fourth type contact hole CTd of FIG. 15. FIG. 27 shows the seventh pattern layer 107 of FIG. 15, and the eighth pattern layer 108 and the fifth type contact hole CTe of FIG. 16. FIG. 28 illustrates the tenth pattern layer 110 of FIG. 18, and the eleventh pattern layer 111 and the eighth type contact hole CTh of FIG. 19. FIGS. 29A and 29B are cross-sectional views taken along the line I-I′ of FIGS. 8 to 28. Here, FIG. 29A is a cross-sectional view taken along the line I-I′ of FIGS. 8 to 28, and FIG. 29B is a cross-sectional view taken along the line I′-I″ of FIGS. 8 to 28.

As shown in FIG. 8, the display device 10 of the present disclosure may include the driving transistor TD, the switching transistor TS, the compensation transistor TC, the initialization transistor TI, and the emission control transistor TE.

Here, the switching transistor TS and the compensation transistor TC may be disposed on a different layer from the other transistors (e.g., the driving transistor TD, the initialization transistor TI, and the emission control transistor TE). For example, as shown in FIG. 28 and FIG. 29A, the switching transistor TS and the compensation transistor TC may be disposed on the driving transistor TD. For example, N-type transistors (e.g., the switching transistor TS and the compensation transistor TC) including an oxide-based active layer may be disposed on P-type MOSFETs (e.g., the driving transistor TD, the initialization transistor TI, and the emission control transistor TE). In other words, oxide-based transistors may be disposed farther from the substrate SUB than the MOSFETs.

The oxide transistor and the MOSFET may be connected in the third direction through a plurality of pattern layers. For example, as shown in FIG. 29A, a first gate electrode G1 of the driving transistor TD may be connected to a fifth drain region D5 (or fifth drain electrode) of the compensation transistor TC through a first node electrode NE1, a first lower node connection electrode NECa1, a first upper node connection electrode NECb1, and a third drain connection electrode DCE3 disposed along the third direction DR3.

As shown in FIGS. 8, 25, 26, 29A and 29B, the switching transistor TS, which is an oxide transistor, may overlap the initialization transistor TI and the emission control transistor TE, which are MOSFETs, in the third direction DR3. For example, a fourth gate electrode G4 of the switching transistor TS may overlap a third gate electrode G3, a third source region S3, and a third drain region D3 of the initialization transistor TI. Also, the fourth gate electrode G4 of the switching transistor TS may overlap a second gate electrode G2, a second source region S2, and a second drain region D2 of the emission control transistor TE. The fourth gate electrode G4 of the switching transistor TS may overlap the first gate electrode G1 of the driving transistor TD.

As shown in FIGS. 8, 25, 26, 29A and 29B, the compensation transistor TC, which is an oxide transistor, may overlap the driving transistor TD, which is a MOSFET, in the third direction DR3. For example, a fifth gate electrode G5 of the compensation transistor TC may overlap the first gate electrode G1, a first source region S1, and a first drain region D1 of the driving transistor TD.

As the oxide transistor and the MOSFET overlap in the third direction DR3 as described above, the integration density of transistors per unit area may be improved.

As shown in FIGS. 29A and 29B, the display device 10 of the present disclosure may include the substrate SUB, a transistor layer TRL, a capacitor layer CPL, the light emitting element layer EMTL, and the encapsulation layer ENC, which are sequentially stacked along the third direction DR3.

The driving transistor TD, the switching transistor TS, the compensation transistor TC, the initialization transistor TI, and the emission control transistor TE described above may be disposed on the transistor layer TRL. In this case, in the transistor layer TRL, the switching transistor TS and the compensation transistor TC may be disposed on a different layer from the other transistors (e.g., the driving transistor TD, the initialization transistor TI, and the emission control transistor TE).

The capacitor layer CPL may include a plurality of pattern layers for forming the first capacitor C1 and the second capacitor C2.

The substrate SUB shown in FIGS. 29A and 29B may be a silicon substrate, a germanium substrate, or a silicon-germanium substrate. The substrate SUB may be a substrate doped with first type impurities.

As shown in FIGS. 9 and 21, the first pattern layer 101 may be disposed on the substrate SUB (or inside the substrate SUB). The first pattern layer 101 may include, for example, a first well region W1, a second well region W2, and a third well region W3.

Each of the first to third well regions W1 to W3 may be a region doped with second type impurities. The second type impurity may be different from a first type impurity. For example, when the first type impurity is a p-type impurity, the second type impurity may be an n-type impurity. When the first type impurity is an n-type impurity, the second type impurity may be a p-type impurity.

In each of the well regions W1 to W3, a source region, a drain region, and a channel region of a corresponding transistor may be disposed.

For example, as shown in FIGS. 8 and 20, the first source region S1 (or first source electrode) and the first drain region D1 (or first drain electrode) of the driving transistor TD may be disposed in the first well region W1. Each of the first source region S1 and the first drain region D1 may be a region doped with the first type impurities. A first gate electrode G1 of the driving transistor TD may cross and overlap the first well region W1. In a plan view, the first well region W1 crossing the first gate electrode G1 may be defined as two parts, and the first source region S1 may be disposed in any one of the two parts, and the first drain region D1 may be disposed in the other part thereof. In other words, in the first well region W1, the first source region S1 and the first drain region D1 may be disposed on both sides of the first gate electrode G1, respectively, with the first gate electrode G1 interposed therebetween. A first channel region CH1 of the driving transistor TD may be disposed in a part of the first well region W1 overlapping the first gate electrode G1.

In addition, as shown in FIG. 29A, the first source region S1 may include a first low-concentration impurity region LDD1 having an impurity concentration relatively lower than those of other portions of the first source region S1. In other words, a portion of the first source region S1 may include a lower concentration of impurities than other portions of the first source region S1. The first drain region D1 may include a second low-concentration impurity region LDD2 having an impurity concentration relatively lower than those of other portions of the first drain region D1. In other words, a portion of the first drain region D1 may include a lower concentration of impurities than other portions of the first drain region D1.

The first low-concentration impurity region LDD1 and the second low-concentration impurity region LDD2 may be disposed close to the first channel region CH1 of the driving transistor TD. For example, the first low-concentration impurity region LDD1 may be disposed close to the first channel region CH1 to overlap a first spacer SW1, and the second low-concentration impurity region LDD2 may be disposed close to the first channel region CH1 to overlap a second spacer SW2. As such, a distance between a high-concentration impurity region of the first source region S1 and a high-concentration impurity region of the first drain region D1 may increase by the first low-concentration impurity region LDD1 and the second low-concentration impurity region LDD2, and as the distance increases, the length of the first channel region CH1 may eventually increase. Accordingly, punch-through and hot carrier phenomena caused by a short channel may be prevented.

As shown in FIGS. 8, 20 and 28, the second source region S2 (or second source electrode) and the second drain region D2 (or second drain electrode) of the emission control transistor TE may be disposed in the second well region W2. Each of the second source region S2 and the second drain region D2 may be a region doped with the aforementioned first type impurities. The second gate electrode G2 of the emission control transistor TE may cross and overlap the second well region W2. In a plan view, the second well region W2 crossing the second gate electrode G2 may be defined as two parts, and the second source region S2 may be disposed in any one of the two parts, and the second drain region D2 may be disposed in the other part thereof. In other words, in the second well region W2, the second source region S2 and the second drain region D2 may be disposed on both sides of the second gate electrode G2, respectively, with the second gate electrode G2 interposed therebetween. A second channel region CH2 of the emission control transistor TE may be disposed in a part of the second well region W2 overlapping the second gate electrode G2. The second source region S2 and the second drain region D2 may include the aforementioned first low-concentration impurity region LDD1 and second low-concentration impurity region LDD2, respectively.

As shown in FIGS. 8 and 20, the third source region S3 (or third source electrode) and the third drain region D3 (or third drain electrode) of the initialization transistor TI may be disposed in the third well region W3. Each of the third source region S3 and the third drain region D3 may be a region doped with the aforementioned first type impurities. The third gate electrode G3 of the initialization transistor TI may cross and overlap the third well region W3. In a plan view, the third well region W3 crossing the third gate electrode G3 may be defined as two parts, and the third source region S3 may be disposed in any one of the two parts, and the third drain region D3 may be disposed in the other part thereof. In other words, in the third well region W3, the third source region S3 and the third drain region D3 may be disposed on both sides of the third gate electrode G3, respectively, with the third gate electrode G3 interposed therebetween. A third channel region CH3 of the initialization transistor TI may be disposed in a part of the third well region W3 overlapping the third gate electrode G3. The third source region S3 and the third drain region D3 may include the aforementioned first low-concentration impurity region LDD1 and second low-concentration impurity region LDD2, respectively.

As shown in FIG. 29A, a gate insulating layer GTI may be disposed on each of the well regions W1 to W3. For example, the gate insulating layer GTI may be disposed on the channel regions CH1 to CH3 of the well regions W1 to W3. As an example, the gate insulating layer GTI may be disposed on the first channel region CH1 of the driving transistor TD in the first well region W1, and may be disposed on the second channel region CH2 of the emission control transistor TE in the second well region W2.

The gate insulating layer GTI may be formed of, for example, silicon oxide. The gate insulating layer GTI may be formed by an atomic layer deposition (ALD) method.

As shown in FIGS. 10 and 29A, the second pattern layer 102 may be disposed on the gate insulating layer GTI. The second pattern layer 102 may include, for example, a first gate electrode G1, a second gate electrode G2, and a third gate electrode G3.

The first gate electrode G1 may be disposed on the gate insulating layer GTI to overlap a part of the first well region W1. The first gate electrode G1 may extend in a direction crossing the first well region W1 on the gate insulating layer GTI.

The second gate electrode G2 may be disposed on the gate insulating layer GTI to overlap a part of the second well region W2. The second gate electrode G2 may extend in a direction crossing the second well region W2 on the gate insulating layer GTI.

The third gate electrode G3 may be disposed on the gate insulating layer GTI to overlap a part of the third well region W3. The third gate electrode G3 may extend in a direction crossing the third well region W3 on the gate insulating layer GTI.

The first to third gate electrodes G1 to G3 may be formed of, for example, polycrystalline silicon or polycrystalline silicon doped with first type impurities.

As shown in FIG. 29A, the first spacer SW1 may be disposed on one side surface of each of the gate electrodes G1 to G3, and the second spacer SW2 may be disposed on the other side surface of each of the gate electrodes G1 to G3. As an example, the first spacer SW1 may be disposed on a first side surface of the first gate electrode G1, and the second spacer SW2 may be disposed on a second side surface of the first gate electrode G1. The first spacer SW1 may be disposed on the first low-concentration impurity region LDD1, and the second spacer SW2 may be disposed on the second low-concentration impurity region LDD2. Each of the first and second spacers SW1 and SW2 may be formed of an oxide layer, a nitride layer, or an oxynitride layer.

As shown in FIG. 29A, an ohmic contact layer 120 may be disposed on each of the gate electrodes G1 to G3, each of the source regions S1 to S3, and each of the drain regions D1 to D3. As an example, the ohmic contact layer 120 may be disposed on the first gate electrode G1, the first source region S1, the first drain region D1. In one or more embodiments, the ohmic contact layer 120 may be disposed on the second gate electrode G2, the second source region S2, and the second drain region D2. In this case, the ohmic contact layer 120 may be disposed in a region (e.g., a first high-concentration impurity region) other than the first low-concentration impurity region LDD1 in each of the source regions S1 to S3. Further, the ohmic contact layer 120 may be disposed in a region (e.g., a second high-concentration impurity region) other than the second low-concentration impurity region LDD2 in each of the drain regions D1 to D3.

The ohmic contact layer 120 may be formed of, for example, a silicide layer. For example, the silicide layer may be a cobalt silicide layer. The silicide layer may be manufactured by, for example, a self-aligned silicide process.

As shown in FIG. 29A, a passivation layer 135 may be disposed on each ohmic contact layer 120 and each of the spacers SW1 and SW2. For example, the passivation layer 135 may be disposed on the entire surface of the substrate SUB including the ohmic contact layer 120 and the spacers SW1 and SW2. The passivation layer 135 may be formed of, for example, a silicon nitride layer (SiNx).

As shown in FIG. 29A, a first interlayer insulating layer VA1 may be disposed on the passivation layer 135. The first interlayer insulating layer VA1 may be disposed on the entire surface of the substrate SUB including the passivation layer 135.

The first interlayer insulating layer VA1 may be formed of, for example, at least one of a silicon oxide layer (SiOx) or a silicon nitride layer (SiNx).

As shown in FIGS. 11, 21, and 29A, the third pattern layer 103 (e.g., a metal layer) may be disposed on the first interlayer insulating layer VA1. As in the example shown in FIG. 11, the third pattern layer 103 may include the first node electrode NE1, a second node electrode NE2, a third node electrode NE3, a first gate connection electrode GCE1, a second gate connection electrode GCE2, a first source connection electrode SCE1, and a first drain connection electrode DCE1. As an example, FIGS. 29A-29B illustrates that the second node electrode NE2, the first node electrode NE1, the first source connection electrode SCE1, and the third node electrode NE3 are disposed on the first interlayer insulating layer VA1.

As shown in FIGS. 11 and 21, the first node electrode NE1 may be connected to the first gate electrode G1 of the driving transistor TD through the first type contact hole CTa penetrating the first interlayer insulating layer VA1 and the passivation layer 135. For example, as shown in FIG. 29A, the first node electrode NE1 may be connected to the first gate electrode G1 of the driving transistor TD through the second contact hole CT2 penetrating the first interlayer insulating layer VA1 and the passivation layer 135.

As shown in FIGS. 11 and 21, the second node electrode NE2 may be connected to the first drain region D1 of the driving transistor TD and the second source region S2 of the emission control transistor TE through the first type contact hole CTa penetrating the first interlayer insulating layer VA1 and the passivation layer 135. For example, as shown in FIG. 29A, the second node electrode NE2 may be connected to the first drain region D1 of the driving transistor TD through the first contact hole CT1 penetrating the first interlayer insulating layer VA1 and the passivation layer 135.

As shown in FIGS. 11 and 21, the third node electrode NE3 may be connected to the third source region S3 of the initialization transistor TI and the second drain region D2 of the emission control transistor TE through the first type contact hole CTa penetrating the first interlayer insulating layer VA1 and the passivation layer 135. For example, as shown in FIG. 29B, the third node electrode NE3 may be connected to the second drain region D2 of the emission control transistor TE through a sixth contact hole CT6 penetrating the first interlayer insulating layer VA1 and the passivation layer 135.

As shown in FIGS. 11 and 21, the first gate connection electrode GCE1 may be connected to the second gate electrode G2 of the emission control transistor TE through the first type contact hole CTa penetrating the first interlayer insulating layer VA1 and the passivation layer 135.

As shown in FIGS. 11 and 21, the second gate connection electrode GCE2 may be connected to the third gate electrode G3 of the initialization transistor TI through the first type contact hole CTa penetrating the first interlayer insulating layer VA1 and the passivation layer 135.

As shown in FIGS. 11 and 21, the first source connection electrode SCE1 may be connected to the first source region S1 of the driving transistor TD through the first type contact hole CTa penetrating the first interlayer insulating layer VA1 and the passivation layer 135. For example, as shown in FIGS. 29A-29B, the first source connection electrode SCE1 may be connected to the first source region S1 of the driving transistor TD through third, fourth, and fifth contact holes CT3, CT4, and CT5 penetrating the first interlayer insulating layer VA1 and the passivation layer 135.

As shown in FIGS. 11 and 21, the first drain connection electrode DCE1 may be connected to the third drain region D3 of the initialization transistor TI through the first type contact hole CTa penetrating the first interlayer insulating layer VA1 and the passivation layer 135.

The aforementioned first to sixth contact holes CT1 to CT6 may belong to the first type contact hole CTa.

The third metal layer 103 may be formed of, for example, tungsten (W).

In one or more embodiments, a bonding layer and a diffusion barrier layer may be further disposed between the third pattern layer 103 and the inner wall of the first type contact hole CTa. The bonding layer may serve to improve bonding strength between the third pattern layer 103 and the inner wall of the first type contact hole CTa (e.g., the material of the first interlayer insulating layer VA1). The diffusion barrier layer may serve to prevent diffusion of the third pattern layer 103 (e.g., a metal layer) in the first type contact hole CTa. The bonding layer may be disposed between the inner wall of the first type contact hole CTa and the third pattern layer 103. The diffusion barrier layer may be disposed between the bonding layer and the third pattern layer 103.

The bonding layer may be formed of, for example, titanium. The diffusion barrier layer may be formed of a titanium nitride layer.

As shown in FIGS. 29A-29B, a second interlayer insulating layer VA2 may be disposed on the third pattern layer 103. For example, the second interlayer insulating layer VA2 may be disposed on the entire surface of the substrate SUB including the first node electrode NE1, the second node electrode NE2, the third node electrode NE3, the first gate connection electrode GCE1, the second gate connection electrode GCE2, and the first source connection electrode SCE1, and the first drain connection electrode DCE1 described above.

The second interlayer insulating layer VA2 may include the same material as the first interlayer insulating layer VA1 described above.

As shown in FIGS. 12, 22, and 29A, the fourth pattern layer 104 (e.g., a metal layer) may be disposed on the second interlayer insulating layer VA2. As in the example shown in FIG. 12, the fourth pattern layer 104 may include the first gate line GWL, the second gate line GCL, the third gate line GRL, the emission control line EML, a first driving connection electrode VCE1, a first pixel connection electrode PCE1, a first lower node connection electrode NCEa1, a second lower node connection electrode NCEa2, and a ground GND. As an example, FIGS. 29A-29B illustrate that the first gate line GWL, the second gate line GCL, the third gate line GRL, the first driving connection electrode VCE1, the first pixel connection electrode PCE1, the first lower node connection electrode NCEa1, and the ground GND are disposed on the second interlayer insulating layer VA2.

As shown in FIG. 21 and FIG. 22, the third gate line GRL may be connected to the second gate connection electrode GCE2 through the second type contact hole CTb penetrating the second interlayer insulating layer VA2.

As shown in FIG. 22, the emission control line EML may be connected to the first gate connection electrode GCE1 through the second type contact hole CTb penetrating the second interlayer insulating layer VA2.

As shown in FIG. 22, the first driving connection electrode VCE1 may be connected to the first source connection electrode SCE1 through the second type contact hole CTb penetrating the second interlayer insulating layer VA2. For example, as shown in FIG. 29A, the first driving connection electrode VCE1 may be connected to the first source connection electrode SCE1 through an eighth contact hole CT8 penetrating the second interlayer insulating layer VA2.

The first pixel connection electrode PCE1 may be connected to the third node electrode NE3 through the second type contact hole CTb penetrating the second interlayer insulating layer VA2. For example, as shown in FIG. 29B, the first pixel connection electrode PCE1 may be connected to the third node electrode NE3 through a ninth contact hole CT9 penetrating the second interlayer insulating layer VA2.

The first lower node connection electrode NCEa1 may be connected to the first node electrode NE1 through the second type contact hole CTb penetrating the second interlayer insulating layer VA2. For example, as shown in FIG. 29A, the first lower node connection electrode NCEa1 may be connected to the first node electrode NE1 through a seventh contact hole CT7 penetrating the second interlayer insulating layer VA2.

The second lower node connection electrode NCEa2 may be connected to the second node electrode NE2 through the second type contact hole CTb penetrating the second interlayer insulating layer VA2.

The ground GND may be connected to the first drain connection electrode DCE1 through the second type contact hole CTb penetrating the second interlayer insulating layer VA2 (e.g., FIGS. 11-12.

The aforementioned seventh to ninth contact holes CT7 to CT9 may belong to the second type contact hole CTb.

The fourth pattern layer 104 may include, for example, titanium (Ti) and/or aluminum (Al). In addition, the fourth pattern layer 104 may have, for example, a multilayer structure including titanium and aluminum described above.

In one or more embodiments, a bonding layer and a diffusion barrier layer may be further disposed between the fourth pattern layer 104 and the inner wall of the second type contact hole CTb. The bonding layer may serve to improve bonding strength between the fourth pattern layer 104 and the inner wall of the second type contact hole CTb (e.g., the material of the second interlayer insulating layer VA2). The diffusion barrier layer may serve to prevent diffusion of the fourth pattern layer in the second type contact hole CTb. The bonding layer may be disposed between the inner wall of the second type contact hole CTb and the fourth pattern layer 104. The diffusion barrier layer may be disposed between the bonding layer and the fourth pattern layer 104.

The bonding layer may be formed of, for example, titanium. The diffusion barrier layer may be formed of a titanium nitride layer.

As shown in FIGS. 29A-29B, a third interlayer insulating layer VA3 may be disposed on the fourth pattern layer 104. For example, the third interlayer insulating layer VA3 may be disposed on the entire surface of the substrate SUB including the first gate line GWL, the second gate line GCL, the third gate line GRL, the emission control line EML, the first driving connection electrode VCE1, the first pixel connection electrode PCE1, the first lower node connection electrode NCEa1, the second lower node connection electrode NCEa2, and the ground GND.

The third interlayer insulating layer VA3 may include the same material as the first interlayer insulating layer VA1 described above.

As shown in FIGS. 13, 23, and 29A-29B, the fifth pattern layer 105 may be disposed on the third interlayer insulating layer VA3. As in the example shown in FIG. 13, the fifth pattern layer 105 may include a first counter gate electrode GB1, a second counter gate electrode GB2, a first upper node connection electrode NCEb1, a second upper node connection electrode NCEb2, a second pixel connection electrode PCE2, and a second driving connection electrode VCE2. As an example, FIGS. 29A-29B illustrate that the first counter gate electrode GB1, the second counter gate electrode GB2, the first upper node connection electrode NCEb1, the second pixel connection electrode PCE2, and the second driving connection electrode VCE2 are disposed on the third interlayer insulating layer VA3.

As shown in FIG. 23, the first counter gate electrode GB1 may be connected to the first gate line GWL through the third type contact hole CTc penetrating the third interlayer insulating layer VA3.

As shown in FIG. 23, the second counter gate electrode GB2 may be connected to the second gate line GCL through the third type contact hole CTc penetrating the third interlayer insulating layer VA3.

As shown in FIG. 23, the first upper node connection electrode NCEb1 may be connected to the first lower node connection electrode NCEa1 through the third type contact hole CTc penetrating the third interlayer insulating layer VA3. For example, the first upper node connection electrode NCEb1 may be connected to the first lower node connection electrode NCEa1 through an eleventh contact hole CT11 penetrating the third interlayer insulating layer VA3.

As shown in FIGS. 22-23, the second upper node connection electrode NCEb2 may be connected to the second lower node connection electrode NCEa2 through the third type contact hole CTc penetrating the third interlayer insulating layer VA3.

As shown in FIG. 23, the second pixel connection electrode PCE2 may be connected to the first pixel connection electrode PCE1 through the third type contact hole CTc penetrating the third interlayer insulating layer VA3. For example, as shown in FIG. 29B, the second pixel connection electrode PCE2 may be connected to the first pixel connection electrode PCE1 through a twelfth contact hole CT12 penetrating the third interlayer insulating layer VA3.

As shown in FIG. 23, the second driving connection electrode VCE2 may be connected to the first driving connection electrode VCE1 through the third type contact hole CTc penetrating the third interlayer insulating layer VA3. For example, as shown in FIG. 29A, the second driving connection electrode VCE2 may be connected to the first driving connection electrode VCE1 through a tenth contact hole CT10 penetrating the third interlayer insulating layer VA3.

The aforementioned tenth to twelfth contact holes CT10 to CT12 may belong to the third type contact hole CTc.

The fifth pattern layer 105 may include, for example, titanium (Ti) and/or aluminum (Al). In addition, the fifth pattern layer 105 may have, for example, a multilayer structure including titanium and aluminum described above.

In one or more embodiments, a bonding layer and a diffusion barrier layer may be further disposed between the fifth pattern layer 105 and the inner wall of the third type contact hole CTc. The bonding layer may serve to improve bonding strength between the fifth pattern layer 105 and the inner wall of the third type contact hole CTc (e.g., the material of the third interlayer insulating layer VA3). The diffusion barrier layer may serve to prevent diffusion of the fifth pattern layer 105 (e.g., a metal layer) in the third type contact hole CTc. The bonding layer may be disposed between the inner wall of the third type contact hole CTc and the fifth pattern layer 105. The diffusion barrier layer may be disposed between the bonding layer and the fifth pattern layer 105.

The bonding layer may be formed of, for example, titanium. The diffusion barrier layer may be formed of a titanium nitride layer.

As shown in FIGS. 29A-29B, a fourth interlayer insulating layer VA4 may be disposed on the fifth pattern layer 105. For example, the fourth interlayer insulating layer VA4 may be disposed on the entire surface of the substrate SUB including the first counter gate electrode GB1, the second counter gate electrode GB2, the first upper node connection electrode NCEb1, the second upper node connection electrode NCEb2, the second pixel connection electrode PCE2, and the second driving connection electrode VCE2.

The fourth interlayer insulating layer VA4 may include the same material as the first interlayer insulating layer VA1 described above.

As shown in FIGS. 14, 24, 29A, and 29B, the sixth pattern layer 106 may be disposed on the fourth interlayer insulating layer VA4. As in the example shown in FIG. 14, the sixth pattern layer 106 may include a first active layer ACT1 and a second active layer ACT2.

The first active layer ACT1 may overlap the first counter gate electrode GB1, the second pixel connection electrode PCE2, and the second driving connection electrode VCE2 on the upper side. As shown in FIGS. 29A and 29B (or FIG. 25), the first active layer ACT1 may include a fourth source region S4 (or fourth source electrode), a fourth drain region D4 (or fourth drain electrode), and a fourth channel region CH4. The fourth channel region CH4 of the switching transistor TS may be formed in a region of the first active layer ACT1 overlapping the first counter gate electrode GB1. The first active layer ACT1 may include oxide. For example, the first active layer ACT1 may be a semiconductor layer including indium-gallium-zinc oxide (IGZO) or indium-gallium-zinc-tin oxide (IGZTO).

The second active layer ACT2 may overlap the second counter gate electrode GB2, the first upper node connection electrode NCEb1, and the second driving connection electrode VCE2 on the lower side. As shown in FIGS. 29A and 29B (or FIG. 25), the second active layer ACT2 may include the fifth source region S5 (or fifth source electrode), a fifth drain region D5 (or fifth drain electrode), and a fifth channel region CH5. The fifth channel region CH5 of the compensation transistor TC may be formed in a region of the second active layer ACT2 overlapping the second counter gate electrode GB2. The second active layer ACT2 may include oxide. For example, the second active layer ACT2 may be a semiconductor layer including indium-gallium-zinc oxide (IGZO) or indium-gallium-zinc-tin oxide (IGZTO).

As shown in FIGS. 29A and 29B, a fifth interlayer insulating layer VA5 may be disposed on the sixth pattern layer 106. For example, the fifth interlayer insulating layer VA5 may be disposed on the entire surface of the substrate SUB including the first active layer ACT1 and the second active layer ACT2 described above.

The fifth interlayer insulating layer VA5 may include the same material as the first interlayer insulating layer VA1 described above.

As shown in FIGS. 15, 25, 26, 29A, and 29B, the seventh pattern layer 107 may be disposed on the fifth interlayer insulating layer VA5. As in the example shown in FIG. 15, the seventh pattern layer 107 may include the fourth gate electrode G4, a second source connection electrode SCE2, a second drain connection electrode DCE2, the fifth gate electrode G5, a third source connection electrode SCE3, the third drain connection electrode DCE3, a third pixel connection electrode PCE3, and a third driving connection electrode VCE3. As an example, FIGS. 29A and 29B illustrate that the third source connection electrode SCE3, the fifth gate electrode G5, the third drain connection electrode DCE3, the third pixel connection electrode PCE3, the second drain connection electrode DCE2, and the fourth gate electrode G4 are disposed on the fifth interlayer insulating layer VA5.

The fourth gate electrode G4 may overlap the first active layer ACT1 and the first counter gate electrode GB1. The fourth channel region CH4 of the switching transistor TS may be formed in a region of the first active layer ACT1 overlapping the fourth gate electrode G4. As shown in FIG. 26, the fourth gate electrode G4 may be connected to the first counter gate electrode GB1 through the fourth type contact hole CTd penetrating the fifth interlayer insulating layer VA5 and the fourth interlayer insulating layer VA4.

The fifth gate electrode G5 may overlap the second active layer ACT2 and the second counter gate electrode GB2. The fifth channel region CH5 of the compensation transistor TC may be formed in a region of the second active layer ACT2 overlapping the fifth gate electrode G5. As shown in FIG. 26, the fifth gate electrode G5 may be connected to the second counter gate electrode GB2 through the fourth type contact hole CTd penetrating the fifth interlayer insulating layer VA5 and the fourth interlayer insulating layer VA4.

The second source connection electrode SCE2 may overlap the fourth source region S4 of the first active layer ACT1 (e.g., FIGS. 25-26). As shown in FIG. 26, the second source connection electrode SCE2 may be connected to the fourth source region S4 through the fourth type contact hole CTd penetrating the fifth interlayer insulating layer VA5.

The second drain connection electrode DCE2 may overlap the fourth drain region D4 of the first active layer ACT1. As shown in FIG. 26 and FIG. 29B, the second drain connection electrode DCE2 may be connected to the fourth drain region D4 through the fourth type contact hole CTd penetrating the fifth interlayer insulating layer VA5. For example, as shown in FIG. 29B, the second drain connection electrode DCE2 may be connected to the fourth drain region D4 through a twentieth contact hole CT20 penetrating the fifth interlayer insulating layer VA5.

The third source connection electrode SCE3 may overlap the fifth source region S5 of the second active layer ACT2. As shown in FIG. 26, the third source connection electrode SCE3 may be connected to the fifth source region S5 through the fourth type contact hole CTd penetrating the fifth interlayer insulating layer VA5. For example, as shown in FIS. 29A, the third source connection electrode SCE3 may be connected to the fifth source region S5 through a thirteenth contact hole CT13 and a fourteenth contact hole CT14 penetrating the fifth interlayer insulating layer VA5. In addition, the third source connection electrode SCE3 may be connected to the second upper node connection electrode NCEb2 through the fourth type contact hole CTd penetrating the fifth interlayer insulating layer VA5 and the fourth interlayer insulating layer VA4.

The third drain connection electrode DCE3 may overlap the fifth drain region D5 of the second active layer ACT2. As shown in FIG. 26, the third drain connection electrode DCE3 may be connected to the fifth drain region D5 through the fourth type contact hole CTd penetrating the fifth interlayer insulating layer VA5. In addition, the third drain connection electrode DCE3 may be connected to the fifth drain region D5 through the fourth type contact hole CTd penetrating the fifth interlayer insulating layer VA5. For example, as shown in FIGS. 29A and 29B, the third drain connection electrode DCE3 may be connected to the fifth drain region D5 through a fifteenth contact hole CT15, a sixteenth contact hole CT16, and a seventeenth contact hole CT17 penetrating the fifth interlayer insulating layer VA5. In addition, the third drain connection electrode DCE3 may be connected to the first upper node connection electrode NCEb1 through an eighteenth contact hole CT18 penetrating the fifth interlayer insulating layer VA5 and the fourth interlayer insulating layer VA4.

As shown in FIG. 26 and FIG. 29B, the third pixel connection electrode PCE3 may be connected to the second pixel connection electrode PCE2 through the fourth type contact hole CTd penetrating the fifth interlayer insulating layer VA5 and the fourth interlayer insulating layer VA4. For example, as shown in FIG. 29B, the third pixel connection electrode PCE3 may be connected to the second pixel connection electrode PCE2 through a nineteenth contact hole CT19 penetrating the fifth interlayer insulating layer VA5 and the fourth interlayer insulating layer VA4.

As shown in FIG. 26, the third driving connection electrode VCE3 may be connected to the second driving connection electrode VCE2 through the fourth type contact hole CTd penetrating the fifth interlayer insulating layer VA5 and the fourth interlayer insulating layer VA4.

The thirteenth to twentieth contact holes CT13 to CT20 may belong to the fourth type contact hole CTd.

The seventh pattern layer 107 may include, for example, titanium (Ti) and/or aluminum (Al). In addition, the seventh pattern layer 107 may have, for example, a multilayer structure including titanium and aluminum described above.

A bonding layer and a diffusion barrier layer may be further disposed between the seventh pattern layer 107 and the inner wall of the fourth type contact hole CTd. The bonding layer may serve to improve bonding strength between the seventh pattern layer 107 and the inner wall of the fourth type contact hole CTd (e.g., the material of the fifth interlayer insulating layer VA5). The diffusion barrier layer may serve to prevent diffusion of the seventh pattern layer 107 (e.g., a metal layer) in the fourth type contact hole CTd. The bonding layer may be disposed between the inner wall of the fourth type contact hole CTd and the seventh pattern layer 107. The diffusion barrier layer may be disposed between the bonding layer and the seventh pattern layer 107.

The bonding layer may include, for example, titanium. The diffusion barrier layer may include a titanium nitride layer.

As shown in FIGS. 29A and 29B, a sixth interlayer insulating layer VA6 may be disposed on the seventh pattern layer 107. For example, the sixth interlayer insulating layer VA6 may be disposed on the entire surface of the substrate SUB including the fourth gate electrode G4, the second source connection electrode SCE2, the second drain connection electrode DCE2, the fifth gate electrode G5, the third source connection electrode SCE3, the third drain connection electrode DCE3, the third pixel connection electrode PCE3, and the third driving connection electrode VCE3 described above.

The sixth interlayer insulating layer VA6 may include the same material as the first interlayer insulating layer VA1 described above.

As shown in FIGS. 16, 27, 29A and 29B, the eighth pattern layer 108 may be disposed on the sixth interlayer insulating layer VA6. As in the example shown in FIG. 16, the eighth pattern layer 108 may include a lower common capacitor electrode CCPEa, a first lower capacitor electrode CPEa1, a second lower capacitor electrode CPEa2, a first data connection electrode DLCE1, and a fourth pixel connection electrode PCE4. As an example, FIGS. 29A and 29B illustrate that the first lower capacitor electrode CPEa1, the lower common capacitor electrode CCPEa, the fourth pixel connection electrode PCE4, and the second lower capacitor electrode CPEa2 are disposed on the sixth interlayer insulating layer VA6.

As shown in FIG. 27, the lower common capacitor electrode CCPEa may be connected to the third drain connection electrode DCE3 through the fifth type contact hole CTe penetrating the sixth interlayer insulating layer VA6. For example, as shown in FIGS. 29A and 29B, the lower common capacitor electrode CCPEa may be connected to the third drain connection electrode DCE3 through a twenty-first contact hole CT21 penetrating the sixth interlayer insulating layer VA6. The lower common capacitor electrode CCPEa may include at least one first extension electrode EXa1 extending along the second direction DR2 and at least one second extension electrode EXa2 extending along the first direction DR1. The second extension electrode EXa2 may have a shape branched from the first extension electrode EXa1. The first extension electrode EXa1 and the second extension electrode EXa2 may be integrally formed.

As shown in FIG. 27, the first lower capacitor electrode CPEa1 may be connected to the third driving connection electrode VCE3 through the fifth type contact hole CTe penetrating the sixth interlayer insulating layer VA6. The first lower capacitor electrode CPEa1 may include at least one first extension electrode EXa11 extending along the second direction DR2 and at least one second extension electrode EXa12 extending along the first direction DR1. The second extension electrode EXa12 may have a shape branched from the first extension electrode EXa11. The first extension electrode EXa11 and the second extension electrode EXa12 may be integrally formed.

The first extension electrode EXa11 of the first lower capacitor electrode CPEa1 may be disposed adjacent to the first extension electrode EXa1 of the lower common capacitor electrode CCPEa. The first capacitor C1 may be formed between the lower common capacitor electrode CCPEa and the first lower capacitor electrode CPEa1. For example, the lower common capacitor electrode CCPEa may include the first electrode of the first capacitor C1, and the first lower capacitor electrode CPEa1 may include the second electrode of the first capacitor C1.

As shown in FIG. 27, the second lower capacitor electrode CPEa2 may be connected to the second source connection electrode SCE2 through the fifth type contact hole CTe penetrating the sixth interlayer insulating layer VA6. The second lower capacitor electrode CPEa2 may include at least one first extension electrode EXa21 extending along the second direction DR2 and at least one second extension electrode EXa22 extending along the first direction DR1. The second extension electrode EXa22 may have a shape branched from the first extension electrode EXa21. The first extension electrode EXa21 and the second extension electrode EXa22 may be integrally formed.

The first extension electrode EXa21 of the second lower capacitor electrode CPEa2 may be disposed adjacent to the first extension electrode EXa1 of the lower common capacitor electrode CCPEa. The second capacitor C2 may be formed between the lower common capacitor electrode CCPEa and the second lower capacitor electrode CPEa2. For example, the lower common capacitor electrode CCPEa may include the second electrode of the second capacitor C2, and the second lower capacitor electrode CPEa2 may include the first electrode of the second capacitor C2.

As shown in FIG. 27, the first data connection electrode DLCE1 may be connected to the second drain connection electrode DCE2 through the fifth type contact hole CTe penetrating the sixth interlayer insulating layer VA6.

As shown in FIG. 27, the fourth pixel connection electrode PCE4 may be connected to the third pixel connection electrode PCE3 through the fifth type contact hole CTe penetrating the sixth interlayer insulating layer VA6. For example, as shown in FIGS. 29A and 29B, the fourth pixel connection electrode PCE4 may be connected to the third pixel connection electrode PCE3 through a twenty-second contact hole CT22 penetrating the sixth interlayer insulating layer VA6.

The twenty-first and twenty-second contact holes CT21 and CT22 may belong to the fifth type contact hole CTe.

The eighth pattern layer 108 may include, for example, titanium (Ti) and/or aluminum (Al). In addition, the eighth pattern layer 108 may have, for example, a multilayer structure including titanium and/or aluminum described above.

In one or more embodiments, a bonding layer and a diffusion barrier layer may be further disposed between the eighth pattern layer 108 and the inner wall of the fifth type contact hole CTe. The bonding layer may serve to improve bonding strength between the eighth pattern layer 108 and the inner wall of the fifth type contact hole CTe (e.g., the material of the sixth interlayer insulating layer VA6). The diffusion barrier layer may serve to prevent diffusion of the eighth pattern layer 108 (e.g., a metal layer) in the fifth type contact hole CTe. The bonding layer may be disposed between the inner wall of the fifth type contact hole CTe and the eighth pattern layer 108. The diffusion barrier layer may be disposed between the bonding layer and the eighth pattern layer 108.

The bonding layer may include, for example, titanium. The diffusion barrier layer may include a titanium nitride layer.

As shown in FIGS. 29A and 29B, a seventh interlayer insulating layer VA7 may be disposed on the eighth pattern layer 108. For example, the seventh interlayer insulating layer VA7 may be disposed on the entire surface of the substrate SUB including the lower common capacitor electrode CCPEa, the first lower capacitor electrode CPEa1, the second lower capacitor electrode CPEa2, the first data connection electrode DLCE1, and the fourth pixel connection electrode PCE4 described above.

The seventh interlayer insulating layer VA7 may include the same material as the first interlayer insulating layer VA1 described above.

As shown in FIGS. 17, 29A, and 29B, a ninth pattern layer 109 may be disposed on the seventh interlayer insulating layer VA7. As in the example shown in FIG. 17, the ninth pattern layer 109 may include an intermediate common capacitor electrode CCPEb, a first intermediate capacitor electrode CPEb1, a second intermediate capacitor electrode CPEb2, a second data connection electrode DLCE2, and a fifth pixel connection electrode PCE5. As an example, FIGS. 29A and 29B illustrate that the first intermediate capacitor electrode CPEb1, the intermediate common capacitor electrode CCPEb, the fifth pixel connection electrode PCE5, and the second intermediate capacitor electrode CPEb2 are disposed on the seventh interlayer insulating layer VA7.

The first intermediate capacitor electrode CPEb1 may have the same shape and the same size (e.g., the same size in the first direction DR1, the second direction DR2, and the third direction DR3) as the first lower capacitor electrode CPEa1. The entire first intermediate capacitor electrode CPEb1 may overlap the entire first lower capacitor electrode CPEa1.

The intermediate common capacitor electrode CCPEb may have the same shape and the same size (e.g., the same size in the first direction DR1, the second direction DR2, and the third direction DR3) as the lower common capacitor electrode CCPEa described above. The entire intermediate common capacitor electrode CCPEb may overlap the entire lower common capacitor electrode CCPEa.

The second intermediate capacitor electrode CPEb2 may have the same shape and the same size (e.g., the same size in the first direction DR1, the second direction DR2, and the third direction DR3) as the second lower capacitor electrode CPEa2. The entire second intermediate capacitor electrode CPEb2 may overlap the entire second lower capacitor electrode CPEa2.

As shown in FIG. 17, the intermediate common capacitor electrode CCPEb may be connected to the lower common capacitor electrode CCPEa through the sixth type contact hole CTf penetrating the seventh interlayer insulating layer VA7. For example, as shown in FIGS. 29A and 29B, the intermediate common capacitor electrode CCPEb may be connected to the lower common capacitor electrode CCPEa through a twenty-ninth contact hole CT29 and a thirtieth contact hole CT30 penetrating the seventh interlayer insulating layer VA7.

The intermediate common capacitor electrode CCPEb may include at least one first extension electrode EXb1 extending along the second direction DR2 and at least one second extension electrode EXb2 extending along the first direction DR1.

The second extension electrode EXb2 may have a shape branched from the first extension electrode EXb1. The first extension electrode EXb1 and the second extension electrode EXb2 may be integrally formed.

As shown in FIG. 17, the first intermediate capacitor electrode CPEb1 may be connected to the first lower capacitor electrode CPEa1 through the sixth type contact hole CTf penetrating the seventh interlayer insulating layer VA7. For example, as shown in FIGS. 29A and 29B, the first intermediate capacitor electrode CPEb1 may be connected to the first lower capacitor electrode CPEa1 through a twenty-third contact hole CT23, a twenty-fourth contact hole CT24, a twenty-fifth contact hole CT25, and a twenty-sixth contact hole CT26 penetrating the seventh interlayer insulating layer VA7. The first intermediate capacitor electrode CPEb1 may include at least one first extension electrode EXb11 extending along the second direction DR2 and at least one second extension electrode EXb12 extending along the first direction DR1. The second extension electrode EXb12 may have a shape branched from the first extension electrode EXb11. The first extension electrode EXb11 and the second extension electrode EXb12 may be integrally formed.

The first extension electrode EXb11 of the first intermediate capacitor electrode CPEb1 may be disposed adjacent to the first extension electrode EXb1 of the intermediate common capacitor electrode CCPEb. The first capacitor C1 may be formed between the intermediate common capacitor electrode CCPEb and the first intermediate capacitor electrode CPEb1. For example, the intermediate common capacitor electrode CCPEb may include the first electrode of the first capacitor C1, and the first intermediate capacitor electrode CPEb1 may include the second electrode of the first capacitor C1.

As shown in FIG. 17, the second intermediate capacitor electrode CPEb2 may be connected to the second lower capacitor electrode CPEa2 through the sixth type contact hole CTf penetrating the seventh interlayer insulating layer VA7. The second intermediate capacitor electrode CPEb2 may include at least one first extension electrode EXb21 extending along the second direction DR2 and at least one second extension electrode EXb22 extending along the first direction DR1. The second extension electrode EXb22 may have a shape branched from the first extension electrode EXb21. The first extension electrode EXb21 and the second extension electrode EXb22 may be integrally formed.

The first extension electrode EXb21 of the second intermediate capacitor electrode CPEb2 may be disposed adjacent to the first extension electrode EXb1 of the intermediate common capacitor electrode CCPEb. The second capacitor C2 may be formed between the intermediate common capacitor electrode CCPEb and the second intermediate capacitor electrode CPEb2. For example, the intermediate common capacitor electrode CCPEb may include the second electrode of the second capacitor C2, and the second intermediate capacitor electrode CPEb2 may include the first electrode of the second capacitor C2.

As shown in FIG. 17, the second data connection electrode DLCE2 may be connected to the first data connection electrode DLCE1 through the sixth type contact hole CTf penetrating the seventh interlayer insulating layer VA7.

As shown in FIG. 17, the fifth pixel connection electrode PCE5 may be connected to the fourth pixel connection electrode PCE4 through the sixth type contact hole CTf penetrating the seventh interlayer insulating layer VA7. For example, as shown in FIGS. 29A and 29B, the fifth pixel connection electrode PCE5 may be connected to the fourth pixel connection electrode PCE4 through a twenty-seventh contact hole CT27 and a twenty-eighth contact hole CT28 penetrating the seventh interlayer insulating layer VA7.

The twenty-third to thirtieth contact holes CT23 to CT30 may belong to the sixth type contact hole CTf.

The ninth pattern layer 109 may include, for example, titanium (Ti) and/or aluminum (Al). In addition, the ninth pattern layer 109 may have, for example, a multilayer structure including titanium and aluminum described above.

In one or more embodiments, a bonding layer and a diffusion barrier layer may be further disposed between the ninth pattern layer 109 and the inner wall of the sixth type contact hole CTf. The bonding layer may serve to improve bonding strength between the ninth pattern layer 109 and the inner wall of the sixth type contact hole CTf (e.g., the material of the seventh interlayer insulating layer VA7). The diffusion barrier layer may serve to prevent diffusion of the ninth pattern layer (e.g., a metal layer) in the sixth type contact hole CTf. The bonding layer may be disposed between the inner wall of the sixth type contact hole CTf and the ninth pattern layer 109. The diffusion barrier layer may be disposed between the bonding layer and the ninth pattern layer 109.

The bonding layer may include, for example, titanium. The diffusion barrier layer may include a titanium nitride layer.

As shown in FIGS. 29A and 29B, an eighth interlayer insulating layer VA8 may be disposed on the ninth pattern layer 109. For example, the eighth interlayer insulating layer VA8 may be disposed on the entire surface of the substrate SUB including the intermediate common capacitor electrode CCPEb, the first intermediate capacitor electrode CPEb1, the second intermediate capacitor electrode CPEb2, the second data connection electrode DLCE2, and the fifth pixel connection electrode PCE5 described above.

The eighth interlayer insulating layer VA8 may include the same material as the first interlayer insulating layer VA1 described above.

As shown in FIGS. 18, 29A, and 29B, a tenth pattern layer 110 may be disposed on the eighth interlayer insulating layer VA8. As in the example shown in FIG. 18, the tenth pattern layer 110 may include an upper common capacitor electrode CCPEc, a first upper capacitor electrode CPEc1, a second upper capacitor electrode CPEc2, a third data connection electrode DLCE3, and a sixth pixel connection electrode PCE6. As an example, FIGS. 29A and 29B illustrate that the first upper capacitor electrode CPEc1, the upper common capacitor electrode CCPEc, the sixth pixel connection electrode PCE6, and the second upper capacitor electrode CPEc2 are disposed on the eighth interlayer insulating layer VA8.

The first upper capacitor electrode CPEc1 may have the same shape and the same size (e.g., the same size in the first direction DR1, the second direction DR2, and the third direction DR3) as the first intermediate capacitor electrode CPEb1. The entire first upper capacitor electrode CPEc1 may overlap the entire first intermediate capacitor electrode CPEb1.

The upper common capacitor electrode CCPEc may have the same shape and the same size (e.g., the same size in the first direction DR1, the second direction DR2, and the third direction DR3) as the intermediate common capacitor electrode CCPEb described above. The entire upper common capacitor electrode CCPEc may overlap the entire intermediate common capacitor electrode CCPEb.

The second upper capacitor electrode CPEc2 may have the same shape and the same size (e.g., the same size in the first direction DR1, the second direction DR2, and the third direction DR3) as the second intermediate capacitor electrode CPEb2. The entire second upper capacitor electrode CPEc2 may overlap the entire second intermediate capacitor electrode CPEb2.

As shown in FIG. 18, the upper common capacitor electrode CCPEc may be connected to the intermediate common capacitor electrode CCPEb through the seventh type contact hole CTg penetrating the eighth interlayer insulating layer VA8. For example, as shown in FIGS. 29A and 29B, the upper common capacitor electrode CCPEc may be connected to the lower common capacitor electrode CCPEa through a thirty-seventh contact hole CT37 and a thirty-eighth contact hole CT38 penetrating the eighth interlayer insulating layer VA8.

The upper common capacitor electrode CCPEc may include at least one first extension electrode EXc1 extending along the second direction DR2 and at least one second extension electrode EXc2 extending along the first direction DR1. The second extension electrode EXc2 may have a shape branched from the first extension electrode EXc1. The first extension electrode EXc1 and the second extension electrode EXc2 may be integrally formed.

As shown in FIG. 18, the first upper capacitor electrode CPEc1 may be connected to the first intermediate capacitor electrode CPEb1 through the seventh type contact hole CTg penetrating the eighth interlayer insulating layer VA8. For example, as shown in FIGS. 29A and 29B, the first upper capacitor electrode CPEc1 may be connected to the second lower capacitor electrode CPEb1 through a thirty-first contact hole CT31, a thirty-second contact hole CT32, a thirty-third contact hole CT33, and a thirty-fourth contact hole CT34 penetrating the eighth interlayer insulating layer VA8. The first upper capacitor electrode CPEc1 may include at least one first extension electrode EXc11 extending along the second direction DR2 and at least one second extension electrode EXc12 extending along the first direction DR1. The second extension electrode EXc12 may have a shape branched from the first extension electrode EXc11. The first extension electrode EXc11 and the second extension electrode EXc12 may be integrally formed.

The first extension electrode EXc11 of the first upper capacitor electrode CPEc1 may be disposed adjacent to the first extension electrode EXc1 of the upper common capacitor electrode CCPEc. The first capacitor C1 may be formed between the upper common capacitor electrode CCPEc and the first upper capacitor electrode CPEc1. For example, the upper common capacitor electrode CCPEc may include the first electrode of the first capacitor C1, and the first upper capacitor electrode CPEc1 may include the second electrode of the first capacitor C1.

As shown in FIG. 18, the second upper capacitor electrode CPEc2 may be connected to the second intermediate capacitor electrode CPEb2 through the seventh type contact hole CTg penetrating the eighth interlayer insulating layer VA8. The second upper capacitor electrode CPEc2 may include at least one first extension electrode EXc21 extending along the second direction DR2 and at least one second extension electrode EXc22 extending along the first direction DR1. The second extension electrode EXc22 may have a shape branched from the first extension electrode EXc21. The first extension electrode EXc21 and the second extension electrode EXc22 may be integrally formed.

The first extension electrode EXc21 of the second upper capacitor electrode CPEc2 may be disposed adjacent to the first extension electrode EXc1 of the upper common capacitor electrode CCPEc. The second capacitor C2 may be formed between the upper common capacitor electrode CCPEc and the second upper capacitor electrode CPEc2. For example, the upper common capacitor electrode CCPEc may include the second electrode of the second capacitor C2, and the second upper capacitor electrode CPEc2 may include the first electrode of the second capacitor C2.

As shown in FIG. 18, the third data connection electrode DLCE3 may be connected to the second data connection electrode DTCE2 through the seventh type contact hole CTg penetrating the eighth interlayer insulating layer VA8.

As shown in FIG. 18, the sixth pixel connection electrode PCE6 may be connected to the fifth pixel connection electrode PCE5 through the seventh type contact hole CTg penetrating the eighth interlayer insulating layer VA8. For example, as shown in FIGS. 29A and 29B, the sixth pixel connection electrode PCE6 may be connected to the fifth pixel connection electrode PCE5 through a thirty-fifth contact hole CT35 and a thirty-sixth contact hole CT36 penetrating the eighth interlayer insulating layer VA8.

The thirty-first to thirty-eighth contact holes CT31 to CT38 may belong to the seventh type contact hole CTg.

The tenth pattern layer 110 may include, for example, titanium (Ti) and/or aluminum (Al). In addition, the tenth pattern layer 110 may have, for example, a multilayer structure including titanium and aluminum described above.

In one or more embodiments, a bonding layer and a diffusion barrier layer may be further disposed between the tenth pattern layer 110 and the inner wall of the seventh type contact hole CTg. The bonding layer may serve to improve bonding strength between the tenth pattern layer 110 and the inner wall of the seventh type contact hole CTg (e.g., the material of the eighth interlayer insulating layer VA8). The diffusion barrier layer may serve to prevent diffusion of the tenth pattern layer (e.g., a metal layer) in the seventh type contact hole CTg. The bonding layer may be disposed between the inner wall of the seventh type contact hole CTg and the tenth pattern layer 110. The diffusion barrier layer may be disposed between the bonding layer and the tenth pattern layer 110.

The bonding layer may include, for example, titanium. The diffusion barrier layer may include a titanium nitride layer.

In one or more embodiments, all of the eighth pattern layer 108, the ninth pattern layer 109, and the tenth pattern layer 110 described above may have the same shape and the same size. Here, the size may mean the size in at least one of the first direction DR1, the second direction DR2, or the third direction DR3.

As shown in FIGS. 29A and 29B, a ninth interlayer insulating layer VA9 may be disposed on the tenth pattern layer 110. For example, the ninth interlayer insulating layer VA9 may be disposed on the entire surface of the substrate SUB including the upper common capacitor electrode CCPEc, the first upper capacitor electrode CPEc1, the second upper capacitor electrode CPEc2, the third data connection electrode DLCE3, and the sixth pixel connection electrode PCE6 described above.

The ninth interlayer insulating layer VA9 may include the same material as the first interlayer insulating layer VA1 described above.

As shown in FIGS. 19, 28, 29A, and 29B, the eleventh pattern layer 111 may be disposed on the ninth interlayer insulating layer VA9. As in the example shown in FIG. 19, the eleventh pattern layer 111 may include the driving voltage line VDL, the data line DL, and a seventh pixel connection electrode PCE7.

As shown in FIG. 28, the driving voltage line VDL may be connected to the first upper capacitor electrode CPEc1 through the eighth type contact hole CTh penetrating the ninth interlayer insulating layer VA9. For example, as shown in FIGS. 29A and 29B, the driving voltage line VDL may be connected to the first upper capacitor electrode CPEc1 through a thirty-ninth contact hole CT39 penetrating the ninth interlayer insulating layer VA9.

As shown in FIG. 28, the data line DL may be connected to the third data connection electrode DLCE3 through the eighth type contact hole CTh penetrating the ninth interlayer insulating layer VA9.

As shown in FIG. 28, the seventh pixel connection electrode PCE7 may be connected to the sixth pixel connection electrode PCE6 through the eighth type contact hole CTh penetrating the ninth interlayer insulating layer VA9. For example, as shown in FIGS. 29A and 29B, the seventh pixel connection electrode PCE7 may be connected to the sixth pixel connection electrode PCE6 through a fortieth contact hole CT40 and a forty-first contact hole CT41 penetrating the ninth interlayer insulating layer VA9.

The thirty-ninth to forty-first contact holes CT39 to CT41 may belong to the eighth type contact hole CTh.

The eleventh pattern layer 111 may include, for example, titanium (Ti) and/or aluminum (Al). In addition, the eleventh pattern layer 111 may have, for example, a multilayer structure including titanium and/or aluminum described above.

In one or more embodiments, a bonding layer and a diffusion barrier layer may be further disposed between the eleventh pattern layer 111 and the inner wall of the eighth type contact hole CTh. The bonding layer may serve to improve bonding strength between the eleventh pattern layer 111 and the inner wall of the eighth type contact hole CTh (e.g., the material of the ninth interlayer insulating layer VA9). The diffusion barrier layer may serve to prevent diffusion of the eleventh pattern layer 111 (e.g., a metal layer) in the eighth type contact hole CTh. The bonding layer may be disposed between the inner wall of the eighth type contact hole CTh and the eleventh pattern layer 111. The diffusion barrier layer may be disposed between the bonding layer and the eleventh pattern layer 111.

The bonding layer may include, for example, titanium. The diffusion barrier layer may include a titanium nitride layer.

As shown in FIGS. 29A and 29B, a tenth interlayer insulating layer VA10 may be disposed on the eleventh pattern layer 111. For example, the tenth interlayer insulating layer VA10 may be disposed on the entire surface of the substrate SUB including the driving voltage line VDL, the data line DL, and the seventh pixel connection electrode PCE7 described above.

The tenth interlayer insulating layer VA10 may include the same material as the first interlayer insulating layer VA1 described above.

As shown in FIGS. 29A and 29B, the light emitting element layer EMTL including the pixel electrode PE as the eleventh pattern layer 111 may be disposed on the tenth interlayer insulating layer VA10. The pixel electrode PE may be connected to the seventh pixel connection electrode PCE7 through a ninth type contact hole penetrating the tenth interlayer insulating layer VA10. In other words, the pixel electrode PE may be connected to the seventh pixel connection electrode PCE7 through a forty-second contact hole CT42 penetrating the tenth interlayer insulating layer VA10. The forty-second contact hole CT42 may belong to a ninth type contact hole.

A light emitting element layer EMTL may include a plurality of light emitting elements LEL having a plurality of pixel electrodes and a bank PDL (or the pixel defining layer) defining a plurality of emission areas EA.

The light emitting elements LEL may include, for example, a first light emitting element (e.g., LEL), a second light emitting element, and a third light emitting element. The first light emitting element LEL may include a first pixel electrode (e.g., PE), a first light emitting layer (e.g., EL) and a common electrode CM. The second light emitting element may include a second pixel electrode, a second light emitting layer and a common electrode CM. The third light emitting element may include a third pixel electrode, a light emitting layer, and a common electrode CM.

A first emission area (e.g., EA), in which the first pixel electrode PE, the first light emitting layer EL, and the common electrode CM are sequentially stacked, indicates an area in which holes from the first pixel electrode PE and electrons from the common electrode CM are combined with each other in the light emitting layer EL to emit light. In this case, the first pixel electrode PE may be an anode electrode of the first light emitting element LEL, and the common electrode CM may be a cathode electrode of the first light emitting element LEL.

In a top emission structure that emits light toward the common electrode CM with respect to the first light emitting layer EL, the first pixel electrode PE may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/AI/ITO) of aluminum and ITO, an APC alloy, and/or a stacked structure (ITO/APC/ITO) of APC alloy and ITO to increase the reflectivity. The APC alloy may be an alloy of silver (Ag), palladium (Pd) and copper (Cu).

The bank PDL (or the pixel defining layer) may define each emission area of each pixel PX. To this end, the bank PDL may be disposed to expose a partial region of each of the first pixel electrode PE, the second pixel electrode, and the third pixel electrode on, for example, the tenth interlayer insulating layer VA10. The bank PDL may cover the edge of each of the first pixel electrode PE, the second pixel electrode, and the third pixel electrode. In one or more embodiments, the bank PDL may be disposed in the seventh type contact hole CTg (e.g., CT29) penetrating the seventh interlayer insulating layer VA7. Accordingly, the twenty-ninth contact hole CT29 penetrating the seventh interlayer insulating layer VA7 may be filled with the bank PDL. The bank PDL may be formed of an organic layer such as acryl resin, epoxy resin, phenolic resin, polyamide resin, polyimide resin, and/or the like.

As shown in FIGS. 29A-29B, a spacer SPC may be disposed on the bank PDL. The spacer SPC may serve to support a mask during a process of manufacturing the light emitting layer (e.g., EL). The spacer SPC may be formed of an organic layer such as acryl resin, epoxy resin, phenolic resin, polyamide resin, polyimide resin, and/or the like.

The first light emitting layer EL may be formed on the first pixel electrode PE. The first light emitting layer EL may include an organic material to emit light in a desired color (e.g., a predetermined color). For example, the first light emitting layer EL may include a hole transporting layer, an organic material layer, and an electron transporting layer. The organic material layer may include a host and a dopant. The organic material layer may include a material that emits desired light (e.g., predetermined light), and may be formed using a phosphorescent material or a fluorescent material.

For example, the organic material layer of the first light emitting layer EL in the first emission area EA, which emits light of a first color (e.g., blue), may include a host material having CBP and/or mCP, and may be a phosphorescent material including a dopant material having (4,6-F2ppy)2Irpic or L2BD111, but the present disclosure is not limited thereto.

An organic material layer of a second light emitting layer of a second emission area EA2 emitting light of a second color (e.g., green) may be a phosphorescent material including a host material including CBP and/or mCP, and a dopant material including Ir (ppy)3(fac tris(2-phenylpyridine) iridium. Alternatively, the organic material layer of the second light emitting layer of the second emission area EA2 emitting the light of the second color may be a fluorescent material including tris(8-hydroxyquinolino)aluminum (Alq3), but the present disclosure is not limited thereto.

For example, an organic material layer of a third light emitting layer of a third emission area EA3 emitting light of a third color (e.g., red) may be a phosphorescent material including a host material including carbazole biphenyl (CBP) or mCP (1,3-bis(carbazol-9-yl), and a dopant including at least one selected from the group consisting of PIQIr(acac)(bis(1-phenylisoquinoline) acetylacetonate iridium), PQIr(acac)(bis(1-phenylquinoline) acetylacetonate iridium), PQIr (tris(1-phenylquinoline) iridium)), and/or PtOEP (octaethylporphyrin platinum). Alternatively, the organic material layer of the third light emitting layer of the third emission area EA3 may be a fluorescent material including PBD:Eu (DBM)3(Phen) or Perylene, but the present disclosure is not limited thereto.

The common electrode CM may be disposed on the first emission layer EL, the second emission layer, and the third emission layer. The common electrode CM may be disposed to cover the first, second, and third light emitting layers. The common electrode CM may be a common layer commonly disposed in the first to third light emitting layers. A capping layer may be formed on the common electrode CM.

In the top emission structure, the common electrode CM may be formed of a transparent conductive material (TCO) such as ITO and/or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

The encapsulation layer ENC may be formed on the light emitting element layer EMTL. The encapsulation layer ENC may include at least one inorganic layer TFE1 and TFE3 to prevent oxygen or moisture from permeating into the light emitting element layer EMTL. In addition, the encapsulation layer ENC may include at least one organic layer to protect the light emitting element layer EMTL from foreign substances such as dust. For example, the encapsulation layer ENC may include a first inorganic encapsulation layer TFE1, an organic encapsulation layer TFE2, and a second inorganic encapsulation layer TFE3.

The first inorganic encapsulation layer TFE1 may be disposed on the common electrode CM, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be formed of a multilayer in which one or more inorganic layers of a silicon nitride layer, a silicon oxynitride layer, a silicon oxide layer, a titanium oxide layer, and/or an aluminum oxide layer are alternately stacked. The organic encapsulation layer TFE2 may be an organic layer such as acryl resin, epoxy resin, phenolic resin, polyamide resin, polyimide resin, and/or the like.

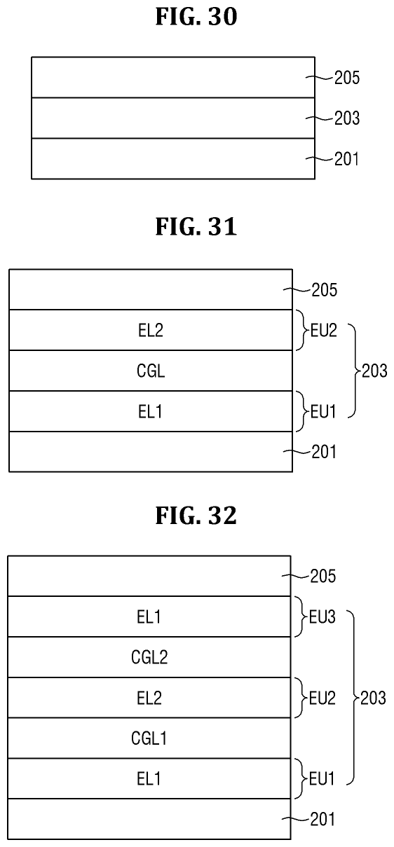

In one or more embodiments, another structure of the light emitting element LEL (e.g., LEL of FIGS. 29A and 29B) will be described with reference to FIGS. 30 to 37.

FIG. 30 is a cross-sectional view illustrating a structure of a display element according to one or more embodiments, and FIGS. 31 to 34 are cross-sectional views illustrating a structure of the light emitting element LEL according to one or more embodiments.

Referring to FIG. 30, the light emitting element LEL (e.g., an organic light emitting diode) according to one or more embodiments may include a pixel electrode 201, a common electrode 205, and an intermediate layer 203 between the pixel electrode 201 and the common electrode 205 described above.

The pixel electrode 201 may include a light-transmitting conductive oxide such as indium tin oxide (ITO), indium zinc oxide (IZO), zinc oxide (ZnO), indium oxide (In₂O₃), indium gallium oxide (IGO), and/or aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chromium (Cr) and/or a compound thereof. For example, the pixel electrode 201 may have a three-layer structure of ITO/Ag/ITO.

The common electrode 205 may be disposed on the intermediate layer 203. The common electrode 205 may include a low work function metal, an alloy, an electrically conductive compound, and/or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, and/or any combination thereof. The common electrode 205 may be a transmissive electrode, a semi-transmissive electrode, or a reflective electrode.

The intermediate layer 203 may include a high molecular material or a low molecular material that emits light of a desired color (e.g., a predetermined color). In addition to various organic materials, the intermediate layer 203 may further include metal-containing compounds such as organometallic compounds, inorganic materials such as quantum dots, and the like.

In one or more embodiments, the intermediate layer 203 may include one light emitting layer and a first functional layer and a second functional layer respectively disposed below and above the one light emitting layer. The first functional layer may include, for example, a hole transport layer HTL or may include the hole transport layer and a hole injection layer HIL. The second functional layer is a component disposed on the light emitting layer and is optional. For example, the intermediate layer 203 may or may not include the second functional layer. The second functional layer may include an electron transport layer ETL and/or an electron injection layer EIL.

In one or more embodiments, the intermediate layer 203 may include two or more light emitting units that are sequentially stacked between the pixel electrode and the common electrode 205, and a charge generation layer CGL disposed between the two light emitting units. When the intermediate layer 203 includes a light emitting unit and a charge generation layer, the light emitting element LEL (e.g., an organic light emitting diode) may be a tandem light emitting element. The light emitting element LEL (e.g., an organic light emitting diode) may improve color purity and luminous efficiency by having a stacked structure of a plurality of light emitting units.

One light emitting unit may include a light emitting layer and a first functional layer and a second functional layer respectively disposed below and above the light emitting layer. The charge generation layer CGL may include a negative charge generation layer and a positive charge generation layer. The luminous efficiency of an organic light emitting diode, which is a tandem light emitting element having a plurality of light emitting layers, may be further increased by the negative charge generation layer and the positive charge generation layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

In one or more embodiments, as illustrated in FIG. 31, the light emitting element LEL (e.g., an organic light emitting diode) may include a first light emitting unit EU1 including a first light emitting layer EL1 and a second light emitting unit EU2 including a second light emitting layer EL2 that are sequentially stacked. The charge generation layer CGL may be disposed between the first light emitting unit EU1 and the second light emitting unit EU2. For example, the light emitting element LEL (e.g., an organic light emitting diode) may include the pixel electrode 201, the first light emitting layer EL1, the charge generation layer CGL, the second light emitting layer EL2, and the common electrode 205 that are sequentially stacked. The first functional layer and the second functional layer may be disposed on and under the first light emitting layer EL1, respectively. The first functional layer and the second functional layer may be included below and above the second light emitting layer EL2, respectively. The first light emitting layer EL1 may be a blue light emitting layer, and the second light emitting layer EL2 may be a yellow light emitting layer.

In one or more embodiments, as illustrated in FIG. 32, the light emitting element LEL (e.g., an organic light emitting diode) may include the first light emitting unit EU1 and the third light emitting unit EU3 including the first light emitting layer EL1, and the second light emitting unit EU2 including the second light emitting layer EL2. The first charge generation layer CGL1 may be disposed between the first light emitting unit EU1 and the second light emitting unit EU2, and the second charge generation layer CGL2 may be disposed between the second light emitting unit EU2 and the third light emitting unit EU3. For example, the light emitting element LEL (e.g., an organic light emitting diode) may include the pixel electrode 201, the first light emitting layer EL1, the first charge generation layer CGL1, the second light emitting layer EL2, the second charge generation layer CGL2, the first light emitting layer EL1, and the common electrode 205 that are sequentially stacked. The first functional layer and the second functional layer may be disposed on and under the first light emitting layer EL1, respectively. The first functional layer and the second functional layer may be disposed on and below the second light emitting layer EL2, respectively. The first light emitting layer EL1 may be a blue light emitting layer, and the second light emitting layer EL2 may be a yellow light emitting layer.

In one or more embodiments, in the light emitting element LEL (e.g., an organic light emitting diode), the second light emitting unit EU2 may further include a third light emitting layer EL3 and/or a fourth light emitting layer EL4 directly in contact with the second light emitting layer EL2 below and/or above the second light emitting layer EL2, in addition to the second light emitting layer EL2. Here, direct contact may mean that no other layer is disposed between the second light emitting layer EL2 and the third light emitting layer EL3 and/or between the second light emitting layer EL2 and the fourth light emitting layer EL4. The third light emitting layer EL3 may be a red light emitting layer, and the fourth light emitting layer EL4 may be a green light emitting layer.

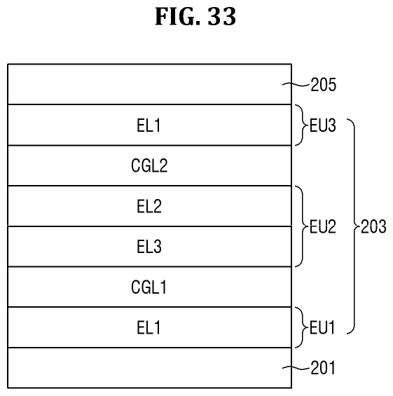

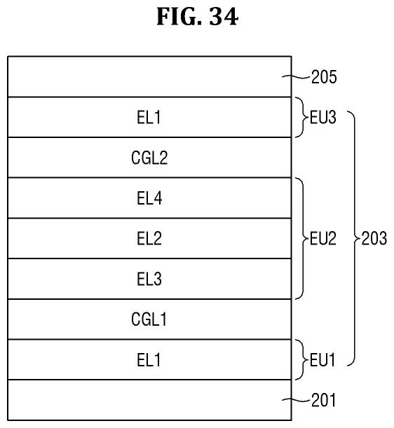

For example, as illustrated in FIG. 33, the light emitting element LEL (e.g., an organic light emitting diode) may include the pixel electrode 201, the first light emitting layer EL1, the first charge generation layer CGL1, the third light emitting layer EL3, the second light emitting layer EL2, the second charge generation layer CGL2, the first light emitting layer EL1, and the common electrode 205 that are sequentially stacked. Alternatively, as illustrated in FIG. 34, the light emitting element LEL (e.g., an organic light emitting diode) may include the pixel electrode 201, the first light emitting layer EL1, the first charge generation layer CGL1, the third light emitting layer EL3, the second light emitting layer EL2, the fourth light emitting layer EL4, the second charge generation layer CGL2, the first light emitting layer EL1, and the common electrode 205 that are sequentially stacked.

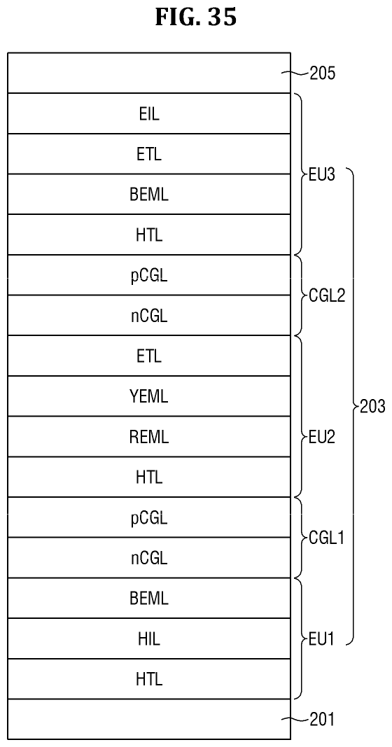

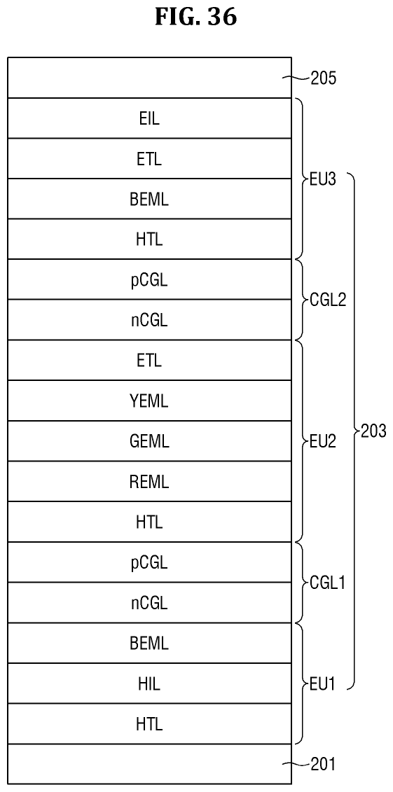

FIG. 35 is a cross-sectional view illustrating an example of the organic light emitting diode of FIG. 33, and FIG. 36 is a cross-sectional view illustrating an example of the organic light emitting diode of FIG. 34.

Referring to FIG. 35, the light emitting element LEL (e.g., an organic light emitting diode) may include the first light emitting unit EU1, the second light emitting unit EU2, and the third light emitting unit EU3 that are sequentially stacked. The first charge generation layer CGL1 may be disposed between the first light emitting unit EU1 and the second light emitting unit EU2, and the second charge generation layer CGL2 may be disposed between the second light emitting unit EU2 and the third light emitting unit EU3. The first charge generation layer CGL1 and the second charge generation layer CGL2 may include a negative charge generation layer nCGL and a positive charge generation layer pCGL.

The first light emitting unit EU1 may include a blue light emitting layer BEML. The first light emitting unit EU1 may further include the hole injection layer HIL and the hole transport layer HTL between the pixel electrode 201 and the blue light emitting layer BEML. In one or more embodiments, a p-doped layer may be further included between the hole injection layer HIL and the hole transport layer HTL. The P-doped layer may be formed by doping the hole injection layer HIL with a p-type doping material. In one or more embodiments, at least one of a blue light auxiliary layer, an electron blocking layer, or a buffer layer may be further included between the blue light emitting layer BEML and the hole transport layer HTL. The blue light auxiliary layer may increase light emission efficiency of the blue light emitting layer BEML. The blue light auxiliary layer may increase light emission efficiency of the blue light emitting layer BEML by adjusting hole charge balance. The electron blocking layer may prevent electron injection into the hole transport layer HTL. The buffer layer may compensate for a resonance distance according to a wavelength of light emitted from the light emitting layer.

The second light emitting unit EU2 may include a yellow light emitting layer YEML and a red light emitting layer REML directly in contact with the yellow light emitting layer YEML below the yellow light emitting layer YEML. The second light emitting unit EU2 may further include the hole transport layer HTL between the positive charge generation layer pCGL of the first charge generation layer CGL1 and the red light emitting layer REML, and may further include the electron transport layer ETL between the yellow light emitting layer YEML and the negative charge generation layer nCGL of the second charge generation layer CGL2.

The third light emitting unit EU3 may include the blue light emitting layer BEML. The third light emitting unit EU3 may further include the hole transport layer HTL between the positive charge generation layer pCGL of the second charge generation layer CGL2 and the blue light emitting layer BEML. The third light emitting unit EU3 may further include the electron transport layer ETL and the electron injection layer EIL between the blue light emitting layer BEML and the common electrode 205. The electron transport layer ETL may have a single layer and/or a multilayer. In one or more embodiments, at least one of a blue light auxiliary layer, an electron blocking layer, and/or a buffer layer may be further included between the blue light emitting layer BEML and the hole transport layer HTL. At least one of a hole blocking layer or a buffer layer may be further included between the blue light emitting layer BEML and the electron transport layer ETL. The hole blocking layer may prevent hole injection into the electron transport layer ETL.

The light emitting element LEL (e.g., an organic light emitting diode) illustrated in FIG. 36 is different from the light emitting element LEL (e.g., an organic light emitting diode) illustrated in FIG. 34 in the stacked structure of the second light emitting unit EU2, and other configurations are the same. Referring to FIG. 36, the second light emitting unit EU2 may include the green light emitting layer GEML, the red light emitting layer REML directly in contact with the green light emitting layer GEML below the green light emitting layer GEML, and a yellow light emitting layer YEML directly in contact with the green light emitting layer GEML above the green light emitting layer GEML. The second light emitting unit EU2 may further include the hole transport layer HTL between the positive charge generation layer pCGL of the first charge generation layer CGL1 and the red light emitting layer REML, and may further include the electron transport layer ETL between the yellow light emitting layer YEML and the negative charge generation layer nCGL of the second charge generation layer CGL2.

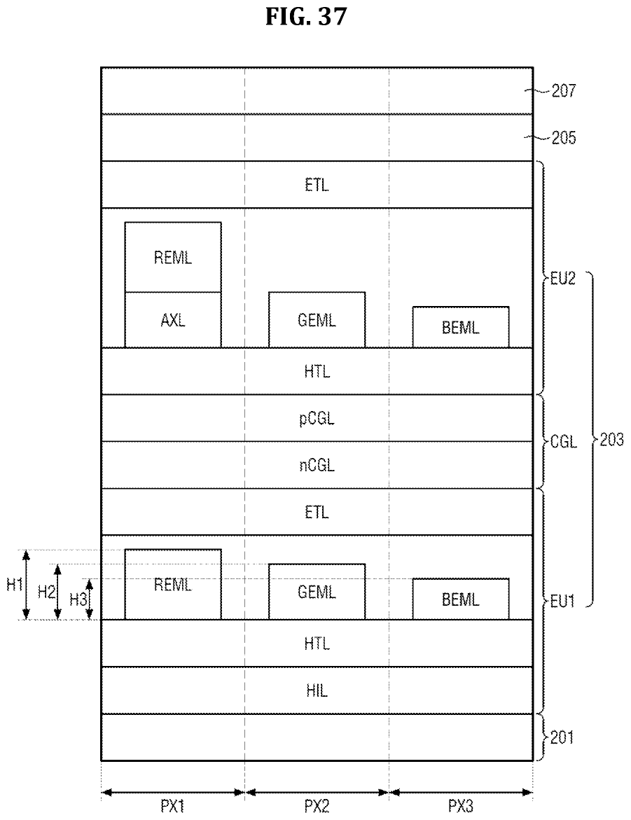

FIG. 37 is a cross-sectional view illustrating a structure of a pixel of a display device according to one or more embodiments.

Referring to FIG. 37, the display panel 100 of the display device 10 may include a plurality of pixels (e.g., the sub-pixels described above). The plurality of pixels may include the first pixel PX1, the second pixel PX2, and the third pixel PX3. Each of the first pixel PX1, the second pixel PX2, and the third pixel PX3 may include the pixel electrode 201, the common electrode 205, and the intermediate layer 203. In one or more embodiments, the first pixel PX1 may be a red pixel, the second pixel PX2 may be a green pixel, and the third pixel PX3 may be a blue pixel.

The pixel electrode 201 may be independently provided in each of the first pixel PX1, the second pixel PX2, and the third pixel PX3.

The intermediate layer 203 of each of the first pixel PX1, the second pixel PX2, and the third pixel PX3 may include the first emitting unit EU1 and the second emitting unit EU2 that are sequentially stacked, and the charge generation layer CGL between the first emitting unit EU1 and the second emitting unit EU2. The charge generation layer CGL may include the negative charge generation layer nCGL and the positive charge generation layer pCGL. The charge generation layer CGL may be a common layer continuously formed in the first pixel PX1, the second pixel PX2, and the third pixel PX3.

The first emitting unit EU1 of the first pixel PX1 may include the hole injection layer HIL, the hole transport layer HTL, the red light emitting layer REML, and the electron transport layer ETL that are sequentially stacked on the pixel electrode 201. The first emitting unit EU1 of the second pixel PX2 may include the hole injection layer HIL, the hole transport layer HTL, the green light emitting layer GEML, and the electron transport layer ETL that are sequentially stacked on the pixel electrode 201. The first emitting unit EU1 of the third pixel PX3 may include the hole injection layer HIL, the hole transport layer HTL, the blue light emitting layer BEML, and the electron transport layer ETL that are sequentially stacked on the pixel electrode 201. Each of the hole injection layer HIL, the hole transport layer HTL, and the electron transport layer ETL of the first emitting unit EU1 may be a common layer continuously formed in the first pixel PX1, the second pixel PX2, and the third pixel PX3.

The second emitting unit EU2 of the first pixel PX1 may include the hole transport layer HTL, an auxiliary layer AXL, the red light emitting layer REML, and the electron transport layer ETL that are sequentially stacked on the charge generation layer CGL. The second emitting unit EU2 of the second pixel PX2 may include the hole transport layer HTL, the green light emitting layer GEML, and the electron transport layer ETL that are sequentially stacked on the charge generation layer CGL. The second emitting unit EU2 of the third pixel PX3 may include the hole transport layer HTL, the blue light emitting layer BEML, and the electron transport layer ETL that are sequentially stacked on the charge generation layer CGL. Each of the hole transport layer HTL and the electron transport layer ETL of the second emitting unit EU2 may be a common layer continuously formed in the first pixel PX1, the second pixel PX2, and the third pixel PX3. In one or more embodiments, at least one of a hole blocking layer or a buffer layer may be further included between the light emitting layer and the electron transport layer ETL in the second emitting unit EU2 of the first pixel PX1, the second pixel PX2, and the third pixel PX3.

A thickness H1 of the red light emitting layer REML, a thickness H2 of the green light emitting layer GEML, and a thickness H3 of the blue light emitting layer BEML may be determined according to the resonance distance. The auxiliary layer AXL may be a layer added to adjust the resonance distance, and may include a resonance auxiliary material. For example, the auxiliary layer AXL may include the same material as the hole transport layer HTL.

In FIG. 37, the auxiliary layer AXL may be disposed only in the first pixel PX1, but the present disclosure is not limited thereto. For example, the auxiliary layer AXL may be disposed in at least one of the first pixel PX1, the second pixel PX2, or the third pixel PX3 to adjust the resonance distance of each of the first pixel PX1, the second pixel PX2, and the third pixel PX3.

The display panel of the display device 1 may further include a capping layer 207 disposed outside the common electrode 205. The capping layer 207 may serve to improve luminous efficiency by the principle of constructive interference. Accordingly, the light extraction efficiency of the light emitting element LEL (e.g., an organic light emitting diode) may be increased, so that the luminous efficiency of the light emitting element LEL (e.g., an organic light emitting diode) may be improved.

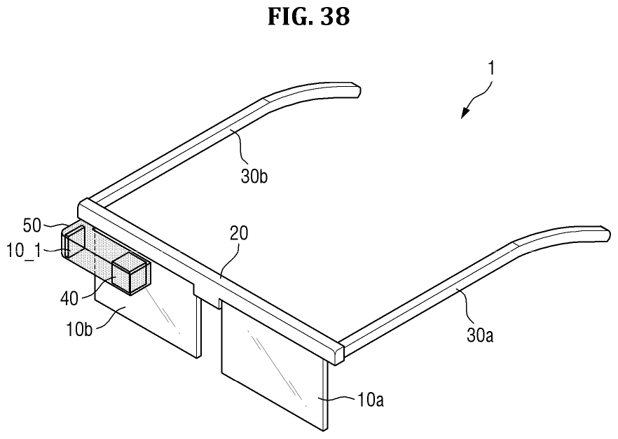

FIG. 38 is an example diagram illustrating a virtual reality device including a display device according to one or more embodiments. FIG. 38 illustrates a virtual reality device 1 to which a display device 10_1 according to one or more embodiments is applied. Here, the display device 10_1 may be, for example, a display device including the components of FIGS. 1 to 37 described above.

Referring to FIG. 38, the virtual reality device 1 according to one or more embodiments may be a glass-type device. The virtual reality device 1 according to one or more embodiments may include the display device 10_1, a left lens 10a, a right lens 10b, a support frame 20, temples 30a and 30b, a reflection member 40, and a display device storage 50.

Although FIG. 38 illustrates the virtual reality device 1 including the temples 30a and 30b, the virtual reality device 1 according to one or more embodiments may be applied to a head mounted display including a head mounted band that may be worn on a head, instead of the temples 30a and 30b. That is, the virtual reality device 1 according to one or more embodiments is not limited to that shown in FIG. 38, and may be applied in various forms to various electronic devices.

The display device storage 50 may include the display device 10_1 and the reflection member 40. The image displayed on the display device 10_1 may be reflected by the reflection member 40 and provided to a user's right eye through the right lens 10b. Accordingly, the user can view the virtual reality image displayed on the display device 10_1 through the right eye.

FIG. 38 illustrates that the display device housing 50 is disposed at the right end of the support frame 20, but the present disclosure is not limited thereto. For example, the display device storage 50 may be disposed at the left end of the support frame 20, and in this case, the image displayed on the display device 10_1 may be reflected by the reflection member 40 and provided to a user's left eye through the left lens 10a. Accordingly, the user can view the virtual reality image displayed on the display device 10_1 through the left eye. Alternatively, the display device storage 50 may be disposed at both the left end and the right end of the support frame 20. In that case, the user can view the virtual reality image displayed on the display device 10_1 through both the left eye and the right eye.

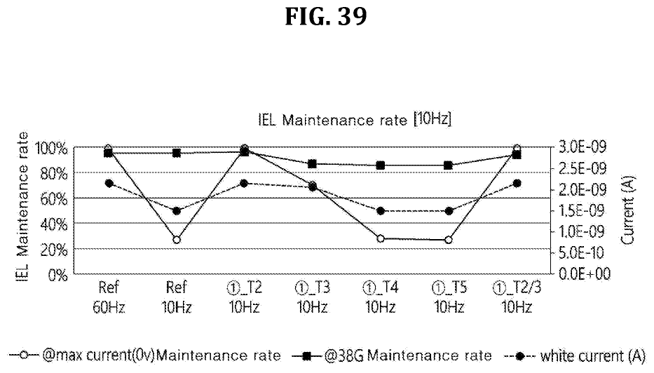

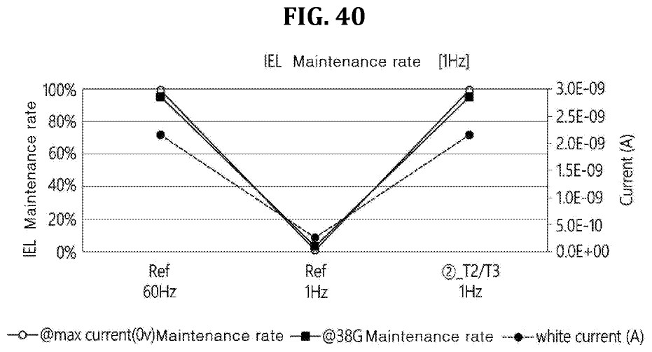

FIGS. 39 and 40 are diagrams for explaining the effects of the present disclosure.

In FIGS. 39 and 40, “Ref 60 Hz” on an X-axis refers to a case in which the display device is driven at 60 Hz (e.g., a first criterion). For example, the first criterion refers to a maintenance rate of a driving current required when the display device is driven at 60 Hz.

In FIG. 39, “Ref 10 Hz” on the X-axis refers to a case in which the display device is driven at 10 Hz (e.g., a second criterion). For example, the second criterion refers to a maintenance rate of a driving current required when the display device is driven at 10 Hz.

In FIG. 40, “Ref 1 Hz” on the X-axis refers to a case in which the display device is driven at 1 Hz (e.g., a third criterion). For example, the third criterion refers to a maintenance rate of a driving current required when the display device is driven at 1 Hz.

In FIG. 39, “\textcircled{1}_T2 10 Hz” on the X-axis refers to a case in which the display device is driven at 10 Hz when the driving transistor TD, the compensation transistor TC, the emission control transistor TE, and the initialization transistor TI of FIG. 5 include a non-oxide semiconductor (e.g., a low-temperature polycrystaline silicon (LTPS) semiconductor), and only the switching transistor TS includes an oxide-based semiconductor (e.g., indium-gallium-zinc-oxide (IGZO) or indium-gallium-zinc-tin-oxide (IGZTO).

In FIG. 39, “\textcircled{1}_T3 10 Hz” on the X-axis refers to a case in which the display device is driven at 10 Hz when the driving transistor TD, the switching transistor TS, the emission control transistor TE, and the initialization transistor TI of FIG. 5 include a non-oxide semiconductor (e.g., a low-temperature polycrystaline silicon (LTPS) semiconductor), and only the compensation transistor TC includes an oxide-based semiconductor (e.g., indium-gallium-zinc-oxide (IGZO) or indium-gallium-zinc-tin-oxide (IGZTO).

In FIG. 39, “\textcircled{1}_T4 10 Hz” on the X-axis refers to a case in which the display device is driven at 10 Hz when the driving transistor TD, the switching transistor TS, the compensation transistor TC, and the initialization transistor TI of FIG. 5 include a non-oxide semiconductor (e.g., a low-temperature polycrystaline silicon (LTPS) semiconductor), and only the emission control transistor TE includes an oxide-based semiconductor (e.g., indium-gallium-zinc-oxide (IGZO) or indium-gallium-zinc-tin-oxide (IGZTO).

In FIG. 39, “\textcircled{1}_T5 10 Hz” on the X-axis refers to a case in which the display device is driven at 10 Hz when the driving transistor TD, the switching transistor TS, the compensation transistor TC, and the emission control transistor TE of FIG. 5 include a non-oxide semiconductor (e.g., a low-temperature polycrystaline silicon (LTPS) semiconductor), and only the initialization transistor TI includes an oxide-based semiconductor (e.g., indium-gallium-zinc-oxide (IGZO) or indium-gallium-zinc-tin-oxide (IGZTO).

In FIG. 39, “\textcircled{1}_T2/3 10 Hz” on the X-axis refers to a case in which the display device is driven at 10 Hz when the driving transistor TD, the emission control transistor TE, and the initialization transistor TS of FIG. 5 include a non-oxide semiconductor (e.g., a low-temperature polycrystaline silicon (LTPS) semiconductor), and the switching transistor TS and the compensation transistor TC include an oxide-based semiconductor (e.g., indium-gallium-zinc-oxide (IGZO) or indium-gallium-zinc-tin-oxide (IGZTO).

In FIG. 39, “\textcircled{1}_T2/3 10 Hz” on the X-axis refers to a case in which the display device is driven at 10 Hz when the driving transistor TD, the emission control transistor TE, and the initialization transistor TS of FIG. 5 include a non-oxide semiconductor (e.g., a low-temperature polycrystaline silicon (LTPS) semiconductor), and the switching transistor TS and the compensation transistor TC include an oxide-based semiconductor (e.g., indium-gallium-zinc-oxide (IGZO) or indium-gallium-zinc-tin-oxide (IGZTO).

In FIG. 40, “\textcircled{2}_T2/3 1 Hz” on the X-axis refers to a case in which the display device is driven at 1 Hz when the driving transistor TD, the emission control transistor TE, and the initialization transistor TS of FIG. 5 include a non-oxide semiconductor (e.g., a low-temperature polycrystaline silicon (LTPS) semiconductor), and the switching transistor TS and the compensation transistor TC include an oxide-based semiconductor (e.g., indium-gallium-zinc-oxide (IGZO) or indium-gallium-zinc-tin-oxide (IGZTO).

In one or more embodiments, a Y-axis on the left side in FIGS. 39 and 40 refers to a maintenance rate IEL of the driving current flowing through the light emitting element in each case described above, and a Y-axis on the right side in FIG. refers to a value of the driving current.

In addition, a curve corresponding to “@max current” in FIGS. 39 and 40 refers to the driving current maintenance rate and driving current value for each case at a data voltage of 0 V, for example.

In addition, a curve corresponding to “@38G” in FIGS. 39 and 40 refers the driving current maintenance ratio and driving current value for each case at a data voltage of 38 grayscale, for example.

In addition, a curve corresponding to “white current (A)” in FIGS. 39 and 40 refers to the driving current maintenance rate and driving current value for each case at a data voltage of white grayscale, for example.

As shown in FIG. 39, when the switching transistor TS and the compensation transistor TC each include an oxide-based semiconductor, despite being driven at 10 Hz, the driving current maintenance rate of the display device may be substantially similar to that of the first criterion (i.e., the display device driven at 60 Hz). In other words, because the leakage current decreases when the switching transistor TS and the compensation transistor TC each include an oxide-based semiconductor, even at low-speed driving of, e.g., 10 Hz, the driving current maintenance rate in one frame period increases, so that image quality may be improved.

In addition, as shown in FIG. 40, when the switching transistor TS and the compensation transistor TC each include an oxide-based semiconductor, despite being driven at 1 Hz, the driving current maintenance rate of the display device may be substantially similar to that of the first criterion (i.e., the display device driven at 60 Hz). In other words, because the leakage current decreases when the switching transistor TS and the compensation transistor TC each include an oxide-based semiconductor, even at low-speed driving of, e.g., 10 Hz, the driving current maintenance rate in one frame period increases, so that image quality may be improved.

What is claimed is:

1. A display device comprising:
a substrate;
a field effect transistor on the substrate;
an oxide-based transistor on a layer different from the field effect transistor and connected to the field effect transistor through a contact hole in an insulating layer; and
a pixel electrode on the oxide-based transistor.

2. The display device of claim 1, wherein the field effect transistor comprises a metal-oxide-semiconductor field effect transistor (MOSFET).

3. The display device of claim 1, wherein the substrate comprises a silicon substrate.

4. The display device of claim 1, wherein the field effect transistor comprises a driving transistor comprising a gate electrode connected to a first node, a source electrode connected to a driving voltage line, and a drain electrode connected to a second node.

5. The display device of claim 4, wherein the field effect transistor further comprises an emission control transistor comprising a gate electrode connected to an emission control line, a source electrode connected to the second node, and a drain electrode connected to the pixel electrode.

6. The display device of claim 5, wherein the field effect transistor further comprises an initialization transistor comprising a gate electrode connected to a third gate line, a source electrode connected to the pixel electrode, and a drain electrode connected to a ground.

7. The display device of claim 4, wherein the oxide-based transistor comprises a switching transistor comprising a gate electrode connected to a first gate line, a drain electrode connected to a data line, and a source electrode connected to the first node.

8. The display device of claim 7, wherein the oxide-based transistor further comprises a compensation transistor comprising a gate electrode connected to a second gate line, a drain electrode connected to the first node, and a source electrode connected to the second node.

9. The display device of claim 7, further comprising a first capacitor connected between the driving voltage line and the first node.

10. The display device of claim 9, further comprising a second capacitor connected between the source electrode of the switching transistor and the first node.

11. The display device of claim 10, wherein the first capacitor and the second capacitor are on the oxide-based transistor.

12. The display device of claim 4, wherein the driving transistor comprises a dual gate transistor.

13. The display device of claim 1, wherein the field effect transistor comprises a P-type transistor.

14. The display device of claim 1, wherein the oxide-based transistor comprises an N-type transistor.

15. The display device of claim 1, wherein an active layer of the oxide-based transistor comprises indium-gallium-zinc oxide (IGZO) or indium-gallium-zinc-tin oxide (IGZTO).

16. The display device of claim 1, wherein the oxide-based transistor is located farther from the substrate than the field effect transistor is.

17. The display device of claim 1, wherein the pixel electrode is connected to the field effect transistor.

18. The display device of claim 1, wherein the field effect transistor is a double gate transistor.

19. The display device of claim 1, wherein the field effect transistor overlaps the oxide-based transistor.
